(19) United States
(12) Patent Application Publication
(10) Pub. No.: US 2026/0370252 A1
(43) Pub. Date: Nov. 19, 2026

(54) TRANSFORM-BASED BLOCK-WISE CODING USING PREDICTION

(71) Applicant: Fraunhofer-Gesellschaft zur Foerderung der angewandten Forschung e.V., Muenchen (DE)

(72) Inventors: Jonathan Pfaff, Berlin (DE); Heiner Kirchhoffer, Berlin (DE); Christian Helmrich, Berlin (DE); Sophie Pientka, Berlin (DE); Heiko Schwarz, Berlin (DE); Detlev Marpe, Berlin (DE); Thomas Wiegand, Berlin (DE)

(21) Appl. No.: 19/737,743

(22) Filed: Jul. 10, 2026

Related U.S. Application Data
(63) Continuation of application No. PCT/EP2025/050704, filed on Jan. 13, 2025.

(30) Foreign Application Priority Data
Jan. 12, 2024 (EP) 24151743.2

(51) Int. Cl. H04B 1/66; H03M 7/30

(52) U.S. Cl. CPC H04B 1/662; H03M 7/3073; H03M 7/6005; H03M 7/6011

(57) ABSTRACT

A decoder and an encoder for coding a digital time-varying signal from or into a datastream are presented, the decoder decoding each temporally residual-predicted temporal block of the digital time-varying signal by predicting the block using a selected one of a set of prediction modes to obtain a prediction signal, determining a prediction residual signal of the block, and correcting the prediction signal using the prediction residual signal, in determining the prediction residual signal, sequentially decoding second-stage-predicted residual samples of residual samples of the block along a sample order by deriving a second-stage residual sample prediction value for a currently decoded residual sample based on already decoded residual samples within a template of sample positions preceding the currently decoded residual sample in sample order, decoding a second-stage-correction value for the currently decoded residual sample from the datastream, and correcting the second-stage residual sample prediction value using the second-stage-correction value.

### CROSS-REFERENCE TO RELATED APPLICATIONS

This application is a continuation of copending International Application No. PCT/EP2025/050704, filed Jan. 13, 2025, which is incorporated herein by reference in its entirety, and additionally claims priority from European Application No. EP 24 151 743.2, filed Jan. 12, 2024, which is incorporated herein by reference in its entirety.

### TECHNICAL FIELD

Embodiments according to the invention are related to apparatuses and methods for encoding or decoding a digital time-varying signal using an efficient implementation of residual coding.

### BACKGROUND OF THE INVENTION

Digital time-varying signals are commonly used for representation of various data such as biomedical signals or seismic measurements. With progressing digitization, signal accuracy, and remote data access, the amount of data with time-varying signals increases. There is a need for improving one or more of coding compression and coding accuracy of such digital time-varying signals.

### SUMMARY

An embodiment may have a decoder for decoding a digital time-varying signal from a data stream, configured to decode the digital time-varying signal from the data stream in temporal blocks by decoding each temporally residual-predicted temporal block of the digital time-varying signal by predicting the respective temporally residual-predicted temporal block using a selected prediction mode out of a set of prediction modes to acquire a prediction signal, determining a prediction residual signal of the respective temporally residual-predicted temporal block, and correcting the prediction signal using the prediction residual signal, wherein, in the determining the prediction residual signal, sequentially decode second-stage-predicted residual samples of residual samples of the respective temporally residual-predicted temporal block along a sample order by deriving a second-stage residual sample prediction value for a currently decoded second-stage-predicted residual sample based on already decoded residual samples within a template of a predetermined number of sample positions preceding the currently decoded second-stage-predicted residual sample in sample order, decoding a second-stage-correction value for the currently decoded second-stage-predicted residual sample from the data stream, and correcting the second-stage residual sample prediction value using the second-stage-correction value.

Another embodiment may have an encoder for encoding a digital time-varying signal into a data stream, configured to encode the digital time-varying signal into the data stream in temporal blocks by encoding each temporally residual-predicted temporal block of the digital time-varying signal by predicting the respective temporally residual-predicted temporal block using a selected prediction mode out of a set of prediction modes to acquire a prediction signal, and determining a prediction residual signal of the respective temporally residual-predicted temporal block, wherein, in the determining the prediction residual signal, sequentially encode second-stage-predicted residual samples of residual samples of the respective temporally residual-predicted temporal block along a sample order by deriving a second-stage residual sample prediction value for a currently encoded second-stage-predicted residual sample based on already encoded residual samples within a template of a predetermined number of sample positions preceding the currently encoded second-stage-predicted residual sample in sample order, encoding a second-stage-correction value for the currently encoded second-stage-predicted residual sample into the data stream.

According to another embodiment, a method for decoding a digital time-varying signal from a data stream may have the steps of: decoding the digital time-varying signal from the data stream in temporal blocks by decoding each temporally residual-predicted temporal block of the digital time-varying signal by predicting the respective temporally residual-predicted temporal block using a selected prediction mode out of a set of prediction modes to acquire a prediction signal, determining a prediction residual signal of the respective temporally residual-predicted temporal block, and correcting the prediction signal using the prediction residual signal, wherein, in the determining the prediction residual signal, sequentially decode second-stage-predicted residual samples of residual samples of the respective temporally residual-predicted temporal block along a sample order by deriving a second-stage residual sample prediction value for a currently decoded second-stage-predicted residual sample based on already decoded residual samples within a template of a predetermined number of sample positions preceding the currently decoded second-stage-predicted residual sample in sample order, decoding a second-stage-correction value for the currently decoded second-stage-predicted residual sample from the data stream, and correcting the second-stage residual sample prediction value using the second-stage-correction value.

According to another embodiment, a method for encoding a digital time-varying signal into a data stream, the method comprising encoding the digital time-varying signal into the data stream in temporal blocks by encoding each temporally residual-predicted temporal block of the digital time-varying signal by predicting the respective temporally residual-predicted temporal block using a selected prediction mode out of a set of prediction modes to acquire a prediction signal, and determining a prediction residual signal of the respective temporally residual-predicted temporal block, wherein, in the determining the prediction residual signal, sequentially encode second-stage-predicted residual samples of residual samples of the respective temporally residual-predicted temporal block along a sample order by deriving a second-stage residual sample prediction value for a currently encoded second-stage-predicted residual sample based on already encoded residual samples within a template of a predetermined number of sample positions preceding the currently encoded second-stage-predicted residual sample in sample order, encoding a second-stage-correction value for the currently encoded second-stage-predicted residual sample into the data stream.

Another embodiment may have a data stream encoded using the method of the present invention.

Another embodiment may have a non-transitory digital storage medium having a computer program stored thereon to perform the methods of the present invention when said computer program is run by a computer.

In accordance with a first aspect of the present invention, a decoder for decoding a digital time-varying signal from a data stream is provided. The decoder is configured to decode the digital time-varying signal from the data stream in temporal blocks by decoding each temporally residual-predicted temporal block of the digital time-varying signal by predicting the respective temporally residual-predicted temporal block using a selected prediction mode out of a set of prediction modes to obtain a prediction signal, determining a prediction residual signal of the respective temporally residual-predicted temporal block, and correcting the prediction signal using the prediction residual signal, wherein, in the determining the prediction residual signal, sequentially decode second-stage-predicted residual samples of residual samples of the respective temporally residual-predicted temporal block along a sample order by deriving a second-stage residual sample prediction value for a currently decoded second-stage-predicted residual sample based on already decoded residual samples within a template of a predetermined number of sample positions preceding the currently decoded second-stage-predicted residual sample in sample order, decoding a second-stage-correction value for the currently decoded second-stage-predicted residual sample from the data stream, and correcting the second-stage residual sample prediction value using the second-stage-correction value.

According to a second aspect, encoder for encoding a digital time-varying signal into a data stream is provided. The encoder is configured to encode the digital time-varying signal into the data stream in temporal blocks by encoding each temporally residual-predicted temporal block of the digital time-varying signal by predicting the respective temporally residual-predicted temporal block using a selected prediction mode out of a set of prediction modes to obtain a prediction signal, and determining a prediction residual signal of the respective temporally residual-predicted temporal block, wherein, in the determining the prediction residual signal, sequentially encode second-stage-predicted residual samples of residual samples of the respective temporally residual-predicted temporal block along a sample order by deriving a second-stage residual sample prediction value for a currently encoded second-stage-predicted residual sample based on already encoded residual samples within a template of a predetermined number of sample positions preceding the currently encoded second-stage-predicted residual sample in sample order, encoding a second-stage-correction value for the currently encoded second-stage-predicted residual sample into the data stream.

Obtaining a prediction signal and correcting the prediction signal allows reducing redundancies in the time-varying signal, which improve coding efficiency. This is further improved by providing a set of prediction modes, which enables selecting prediction modes better suitable for each respective temporal block. It has been recognized that redundancies can be further reduced by performing a second-stage prediction, which performs, in essence, sample wise prediction using already decoded samples of the temporal block (whereas the first stage essentially forms a block-wise prediction). Due to their vicinity relative to each other, the residual samples may exhibit similar properties (e.g., amplitude and/or slope), which can be used for the second-stage prediction, allowing for further data compression. The use of a template is also accessible to predication methods that can be extended or modified for first samples (e.g., by forming artificial residual samples or using similarities to previous temporal blocks in case of a bypass prediction mode).

According a further aspect, corresponding methods for decoding and encoding a digital time-varying signal into a data stream are provided.

An embodiment is related to a data stream having a digital-time varying signal (e.g., an audio signal, biometric signal, or seismic signal) encoded thereinto using a herein described method for encoding. The data stream may be stored on a storage medium (e.g., non-transitory storage medium).

An embodiment is related to a computer program (e.g., stored on a storage medium, e.g., non-transitory storage medium, e.g., computer program product) having a program code for performing, when running on a computer, a herein described method, when being executed on the computer.

### Introductory Remarks:

In the following, aspects of the invention will be described in general terms with reference to FIG. 1A to 2B. Afterwards, different inventive embodiments and aspects will be described in a chapter “Setup”, in a chapter “Sample-wise transforms”, in a chapter “Further embodiment: Combination of sample-wise transform and block-based trigonometric transform”, in a chapter “Further embodiment: Sample-wise transform that also uses sample values from one or more other channels” and in a chapter “Further embodiments”.

Also, further embodiments will be defined by the enclosed claims.

It should be noted that any embodiments as defined by the claims and/or the general description can be supplemented by any of the details (features and functionalities) described in the above mentioned chapters and vice versa.

Also, the embodiments described in the above mentioned chapters can be used individually, and can also be supplemented by any of the features in another chapter, or by any feature included in the claims.

Also, it should be noted that individual aspects described herein can be used individually or in combination. Thus, details can be added to each of said individual aspects without adding details to another one of said aspects.

It should also be noted that the present disclosure describes, explicitly or implicitly, features usable in encoder (apparatus for providing an encoded representation of an input signal). Thus, any of the features described herein can be used in the context of an encoder.

Further, it should also be noted that the present disclosure describes, explicitly or implicitly, features usable in decoder (apparatus for decoding an encoded signal). Thus, any of the features described herein can be used in the context of a decoder.

Moreover, features and functionalities disclosed herein relating to a method can also be used in an apparatus (configured to perform such functionality). Furthermore, any features and functionalities disclosed herein with respect to an apparatus can also be used in a corresponding method. In other words, the methods disclosed herein can be supplemented by any of the features and functionalities described with respect to the apparatuses.

Also, any of the features and functionalities described herein can be implemented in hardware or in software, or using a combination of hardware and software, as will be described in the section “implementation alternatives”.

### BRIEF DESCRIPTION OF THE DRAWINGS

The drawings are not necessarily to scale, emphasis instead generally being placed upon illustrating the principles of the invention. Embodiments of the present invention will be detailed subsequently referring to the appended drawings, in which:

FIG. 1A shows a schematic view of a decoder for decoding a digital time-varying signal from a data stream;

FIG. 1B shows a schematic view of an encoder for encoding a digital time-varying signal into a data stream;

FIG. 2A shows a decoding/encoding of second-stage-predicted residual samples;

FIG. 2B shows a decoding/encoding of first residual samples;

FIG. 3 shows an encoder for encoding a multi-channel digital signal into a datastream as well as decoder for decoding the multi-channel digital signal from the datastream;

FIG. 4 shows a decoder for decoding a multi-channel digital signal using an inter-channel prediction mode; and

FIG. 5 shows a decoder for decoding a multi-channel digital signal using an intra-channel prediction mode.

### DETAILED DESCRIPTION OF THE INVENTION

Equal or equivalent elements or elements with equal or equivalent functionality are denoted in the following description by equal or equivalent reference numerals even if occurring in different figures.

In the following description, a plurality of details is set forth to provide a more throughout explanation of embodiments of the present invention. However, it will be apparent to those skilled in the art that embodiments of the present invention may be practiced without these specific details. In other instances, well-known structures and devices are shown in block diagram form rather than in detail in order to avoid obscuring embodiments of the present invention. In addition, features of the different embodiments described herein after may be combined with each other, unless specifically noted otherwise.

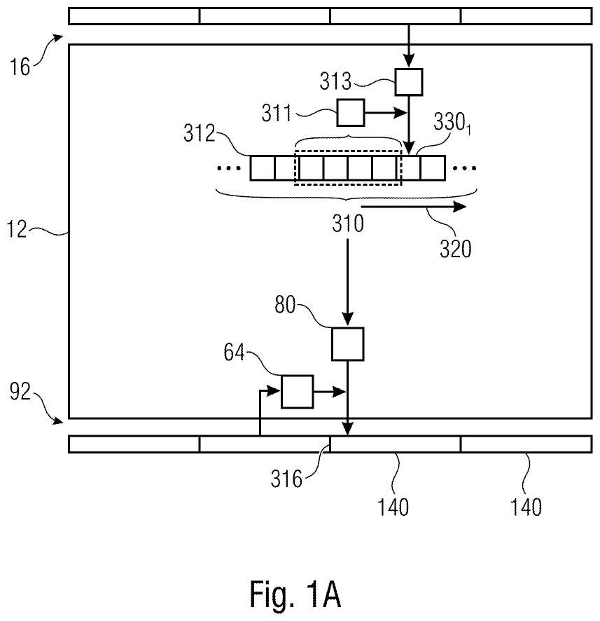

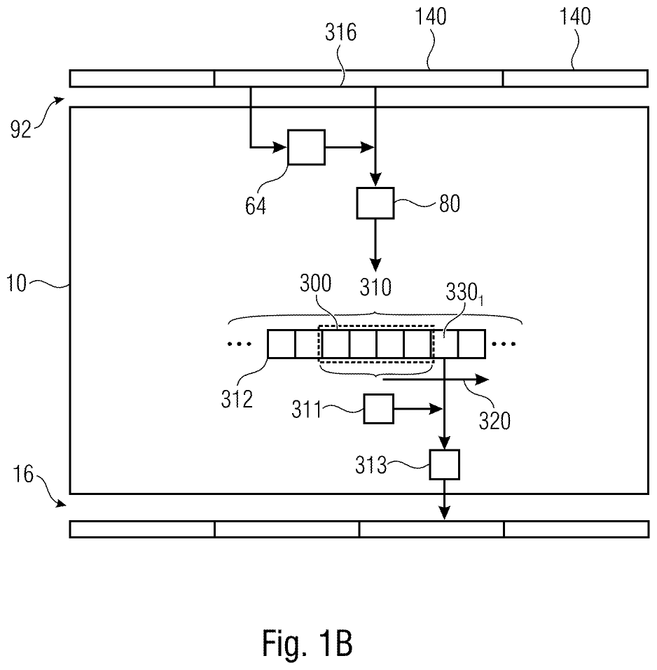

FIG. 1A shows a schematic view of a decoder 12 for decoding a digital time-varying signal 92 from a data stream 16. The decoder 12 may be any decoder 12 disclosed herein and may be configured to decode the data stream 16 of any encoder 10 disclosed herein. Any feature disclosed with reference to FIG. 1A may be used in any combination with any other decoder 12 disclosed herein.

The 12 is configured to decode the digital time-varying signal 92 from the data stream 16 in temporal blocks by decoding each temporally residual-predicted temporal block 140 of the digital time-varying signal 92 by predicting the respective temporally residual-predicted temporal block 140 using a selected prediction mode out of a set of prediction modes to obtain a prediction signal 64, determining a prediction residual signal 80 of the respective temporally residual-predicted temporal block 140, and correcting the prediction signal 64 using the prediction residual signal 80.

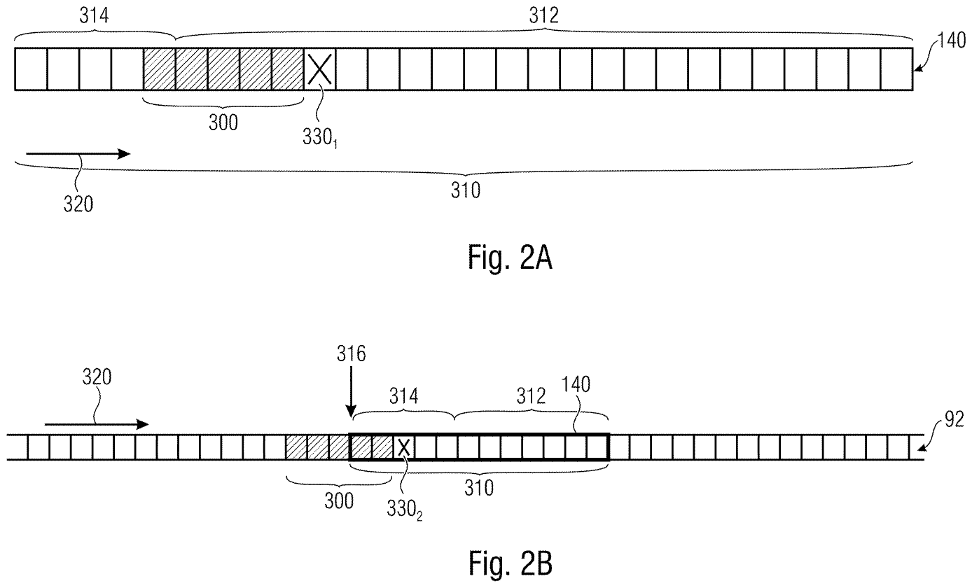

The decoder 12 is configured to, in the determining the prediction residual signal 80, sequentially decode second-stage-predicted residual samples 312 of residual samples 310 (e.g., wherein the residual samples 310 may be all residual samples of the currently coded temporal block 140, e.g., wherein the second-stage-predicted residual samples 312 may be a proper subset of residual samples of the residual samples 310 such as all residual samples after first residual samples 314 discussed further below) of the respective temporally residual-predicted temporal block 140 along a sample order 320 (e.g., the sample order 320 may run in the same direction as a time order, e.g., of the digital time-varying signal 92, e.g., so that a block border 316 of the respective temporally residual-predicted temporal block 140 is a leading border, e.g., as shown in FIG. 2B) by deriving a second-stage residual sample prediction value 311

$$( e . g . , {\sum }_{l = 1}^{K} {a}_{l} \cdot c [ i - l ] )$$

for a currently decoded second-stage-predicted residual sample 330₁ based on already decoded residual samples within a template 300 of a predetermined number (e.g., K, e.g., K=4 in FIG. 1A, e.g., K=5 in FIG. 2A, but any other number can be used instead, e.g., a power of two) of sample positions preceding the currently decoded second-stage-predicted residual sample 330₁ in sample order 320, decoding a second-stage-correction value 313 (e.g., d[i], e.g., see section 2 below) for the currently decoded second-stage-predicted residual sample 330₁ from the data stream 16, and correcting the second-stage residual sample prediction value 311 using the second-stage-correction value 313.

FIG. 1B shows a schematic view of an encoder 10 for encoding a digital time-varying signal 92 into a data stream 16. The encoder 10 may be any encoder 10 disclosed herein and may be configured to encode a data stream 16 decodable by any decoder 12 disclosed herein. Any feature disclosed with reference to FIG. 1B may be used in any combination with any other encoder 10 disclosed herein.

The encoder 10 is configured to encode the digital time-varying signal 92 into the data stream 16 in temporal blocks by encoding each temporally residual-predicted temporal block 140 of the digital time-varying signal 92 by predicting the respective temporally residual-predicted temporal block 140 using a selected prediction mode out of a set of prediction modes to obtain a prediction signal 64, and determining a prediction residual signal 80 of the respective temporally residual-predicted temporal block 140 (e.g., by subtracting the prediction signal 64 from the digital time-varying signal 92 of the respective temporally residual-predicted temporal block 140).

The encoder 10 is configured to, in the determining the prediction residual signal 80, sequentially encode second-stage-predicted residual samples 312 of residual samples 310 of the respective temporally residual-predicted temporal block 140 along a sample order 320 by deriving a second-stage residual sample prediction value 311

$$( e . g . , {\sum }_{l = 1}^{K} {a}_{l} \cdot c [ i - l ] )$$

for a currently encoded second-stage-predicted residual sample 330₁ based on already encoded residual samples within a template 300 of a predetermined number (e.g., K) of sample positions preceding the currently encoded second-stage-predicted residual sample 330₁ in sample order 320, encoding a second-stage-correction value 313 (e.g., d[i]) for the currently encoded second-stage-predicted residual sample 330₁ into the data stream 16 (e.g., the second-stage-correction value 313 is to be usable for correcting the second-stage residual sample prediction value).

The digital time-varying signal 92 may be (or comprise) one channel, for example, as a single channel signal or as part of a multi-channel signal. Alternatively, the digital time-varying signal 92 may comprise one or more channels. A channel may define a single parameter assuming values over time, e.g., wherein the parameter is sampled over temporally successive samples. The temporal block 140 may form a one dimensional array of samples, wherein the sample order 320 defines a sequence order within the one dimensional array of samples. The digital time-varying signal 92 may comprise or be an audio signal (e.g., having one or more audio channels), a biomedical signal (e.g., an electrogram such as obtained by electroencephalography, electrocardiogram, or electrooculography), or a seismic signal. Any decoder 12 disclosed herein may be a decoder 12 for decoding an audiosignal, a biomedical signal, or a seismic signal. Any encoder 10 disclosed herein be an encoder for encoding an audio signal, a biomedical signal, or a seismic signal. The digital time-varying signal 92 may be a predetermined coded channel of coded channels representing a multi-channel digital signal. The multi-channel digital signal may be obtained by at least one of Electrocardiography, Electroencephalography, Electromyography or seismic measurement, and/or the multi-channel digital signal may be a bio-physiological waveform data such as an electroencephalography (EEG) signal, an electrocardiogram (ECG), or an electromyography (EMG) signal, or seismic waveform data.

The digital time-varying signal 92 may be or comprise one or more waveform signals. Any disclosure related herein to examples with a single channel may also be applicable in any combination to a digital time-varying signal 92 being one of multiple channels.

The temporal block 140 may form a one dimensional array of samples, wherein the sample order 320 defines a sequence order within the one dimensional array of samples. The sequence order 320 may define a temporal order and/or a coding order.

The template 300 may define a fixed (or identical) predetermined number of sample positions (e.g., K, e.g., two, three, four, five, six, or larger, e.g., powers of two, such as 8, 16, 32, 64, or higher), e.g., for all second-stage-predicted residual samples 312 of the currently coded temporal block 140, e.g., for all first residual samples 314, e.g., for all residual samples 310 of the currently coded temporal block 140. The predetermined number of sample positions may be a fixed predetermined number for a set of temporal blocks 140 (e.g., bordered by random access borders), for all temporal blocks 140 of the digital time-varying signal 92, or for all temporal blocks of multiple channels of digital time-varying signals. Alternatively, the predetermined number may be signaled (e.g., coded in an overhead or side information). For example, the predetermined number may be signaled for each temporal block, for each set of temporal blocks or at the start of the digital time-varying signal 92. Furthermore, the predetermined number may only be signaled if the predetermined number changes, wherein the use of the signaled predetermined number is assumed until a new predetermined number is signaled.

The prediction mode may be signaled (e.g., encoded and decoded) in the data stream 16, e.g., by an indicator such as an index for a list of prediction modes. The set of prediction modes may be fixed or may be adjustable, e.g., based on a size (e.g., number of samples) of the temporal block 140. For example, certain modes (predicting a slope, e.g., half-slope, e.g., quarter slope) may not be supported (or selectable) if the size of the temporal block exceeds a threshold (e.g., is greater than 64 samples or any other number). A size of the indicator (e.g., a number of bins of a binarization of the indicator) for the mode may be adjusted based on the supported prediction modes (e.g., based on the size of the temporal blocks 140, e.g., 2 bits or 3 bits).

Correcting the prediction signal 64 using the prediction residual signal 80 may be realized by or be based on a linear combination of the prediction signal 64 and the prediction residual signal 80 (e.g., a sum, e.g., a weighted sum). Similarly, the correcting the second-stage residual sample prediction value 311 using the second-stage-correction value 313 may be realized or be based on a linear combination of the second-stage residual sample prediction value 311 using the second-stage-correction value 313 (e.g., a sum, e.g., a weighted sum). The sample positions may immediately precede (e.g., without further samples in-between) the currently decoded second-stage-predicted residual sample 330₁. The sample positions may immediately precede each other (e.g., a sequence of samples with no further samples in-between).

The set of prediction modes may comprises one or more of the following prediction modes.

According to a DC prediction mode (e.g., a mean-prediction mode), the prediction signal of the respective temporal block may be determined to by a constant function (e.g., having a constant value, e.g., “3” or “4”) with a determination of a constant of the constant function based on predetermined already decoded samples preceding the respective temporal block (e.g., based on a mean value, which may optionally be weighted and/or biased),

According to one or more linear prediction modes (e.g., a half-slope prediction mode and/or a quarter-slope prediction mode), the prediction signal of the respective temporal block may be determined by a linear function with a determination of at least one of a slope (e.g., an extrapolation of a slope determined based on immediately preceding samples of a preceding temporal block, e.g., a half slope thereof, e.g., a quarter slope thereof) and an offset (e.g., based on one or more immediately preceding samples) of the linear function based on predetermined already decoded samples preceding the respective temporal block. For example, the slope (or a half or quarter thereof) may be determined based on a slope between two immediately preceding already coded samples. The offset may be determined based on the immediately preceding sample.

According to a block-copy prediction mode (e.g., a prediction mode using signalled temporal offsets), the prediction signal of the respective temporal block may be predicted based on one or more reference block portions (e.g., having the same length as the currently coded temporal block) of already decoded samples preceding the respective temporal block offset relative to the respective temporal block at a position signaled for the respective temporal block in the data stream (e.g., relative to a position that is located an amount of samples of the currently decoded temporal block before an earliest sample of the temporal, e.g., at a position M−N+1, with M already decoded samples and N samples in the currently decoded block, e.g., wherein the prediction signal is determined based on a weighted sum of the referenced temporal blocks). In case of a single reference block portion, the prediction signal may be determined as or may be determined based on a copy of samples of the reference block portion. In case of more than one reference block portions, the prediction signal may be determined as or may be determined based on an average and/or weighted sum of the reference block portions (e.g., sample-wise).

According to a cross-channel prediction mode (e.g., a prediction mode which generates a prediction signal out of multiple portions of already de-coded blocks of channels different from the current channel), the prediction signal of the respective temporal block may be predicted based on one or more reference coded channels out of coded channels which represent a multi-channel signal 14 coded into the data stream and to be decoded from the data stream by the decoder, and one of which is represented by the digital time-varying signal 92. In case of a single reference block portion, the prediction signal may be determined as or may be determined based on a copy of samples of the reference block portion. In case of more than one reference block portions, the prediction signal may be determined as or may be determined based on an average and/or weighted sum of the reference block portions (e.g., sample-wise).

According to a bypass prediction mode (e.g., a prediction mode which generates no prediction or a prediction with a value of zero) according to which the prediction signal of the respective temporal block is set to zero. However, any other combination of modes may be used.

A set of non-bypass prediction modes may comprise one or more of the DC prediction mode, the one or more linear prediction modes, the block-copy prediction mode and the cross-channel prediction mode. The set of non-bypass prediction modes may be changed according to a size of the currently coded temporal block (e.g., a multiple sets may be provided, wherein a set is selected out of the multiple sets based on the size of the temporal block.

FIG. 2A shows a decoding/encoding of second-stage-predicted residual samples 312. FIG. 2A exemplarily depicts a single temporal block 140 with 28 residual samples 310 of which 23 residual samples (28−5) are second-stage-predicted residual samples 312 decoded using a template 300 that spans (or covers or having a range of) five residual samples. The second-stage-predicted residual sample 330₁ indicates a currently decoded residual sample that is decoded using a second stage prediction as described above (e.g., using only residual samples of the currently coded temporal block 140). Optionally are provided five first residual samples 314, which may be decoded differently as described further below. Alternatively, all residual samples 310 may be second-stage-predicted residual samples 312.

FIG. 2B shows a decoding/encoding of first residual samples. The decoding may be performed by any decoder 12 disclosed herein. The encoding may be performed by any encoder 10 disclosed herein. FIG. 2B exemplarily depicts a time-varying signal 92 (e.g., forming a channel), in which a temporal block 140 (with twelve residual samples 310) is currently being decoded. The temporal block 140 is preceded by a previously coded temporal block, wherein a block border 316 indicates a border between said two temporal blocks. FIG. 2B further depicts a first residual sample 330₂, which is located within the first residual samples 214, for which the template 300 extends beyond the block border 316 (or beyond the currently coded temporal block 140). The first residual sample 330₂ may be decoded differently (though partially similarly) than the second-stage-predicted residual sample 330₁ as will be described further below.

As can be seen in the examples of FIG. 2A, 2B, the residual samples 310 may constitute all residual samples of the temporal block 140. However, the second-stage-predicted residual samples 312 (i.e. obtained based on the second-stage residual sample prediction value 311 and the second-stage-correction value 313) may only be a portion (or proper subset) of the residual samples 310 (or may form all residual samples 310). For example, the residual samples 310 may further comprise first residual samples 314, which may be derived differently than the second-stage-predicted residual samples 312 (e.g., as described further below, e.g., in case of a bypass-prediction mode). The residual samples 310 may comprise, for example, only second-stage-predicted residual samples 312, or only second-stage-predicted residual samples 312 and first residual samples 314, or second-stage-predicted residual samples 312 and one or more types of residual samples (e.g., one type of which may be first residual samples 314).

The decoder 12 may be configured to, in the deriving the second-stage residual sample prediction value 311

$$( e . g . , {\sum }_{l = 1}^{K} {a}_{l} \cdot c [ i - l ] ) ,$$

perform a linear prediction based on the already decoded residual samples within the template 300. For example, the decoder 12 may be configured to, in the deriving the second-stage residual sample prediction value 311

$$( e . g . , {\sum }_{l = 1}^{K} {a}_{l} \cdot c [ i - l ] ) ,$$

form a weighted sum of the already decoded residual samples within the template 300.

The decoder 12 may be configured to, in the decoding the second-stage-correction value 313 (e.g., d[i]) for the currently decoded second-stage-predicted residual sample 330₁ from the data stream 16, use entropy decoding. For example, the decoding may comprise using a context coded significance flag (e.g., and/or one or more other flags such as a sign flag and a greater-than-X-flag). The decoding may comprise a truncated unary coding (e.g., Rice coding) of a first part of the second-stage-correction value 313 and using exponential Golomb coding for a remainder portion. At least a portion of the second-stage-correction value 313 (e.g., parts of a binarization thereof) may be coded using context based adaptive binary arithmetic coding (CABAC).

For example, the decoder 12 may be configured to decode each of transform coded temporal blocks (e.g., a block of coefficients, e.g., obtained by transforming a corresponding temporal block 140 into a transform domain, such as a frequency domain, wherein the transform coded block may contain coefficients that may be a different number or same number as samples of the corresponding temporal block 140) of the temporally residual-predicted temporal blocks 140 by deriving the second-stage-correction value 313 of the second-stage-predicted residual samples (e.g., in the sequentially decoding the second-stage-predicted residual samples, deriving the second-stage-correction value 313 for the currently decoded second-stage-predicted residual sample) by means of a re-transformation (e.g., which may at least partially reverse a transformation applied by the encoder 10, e.g., a re-transformation from a frequency domain to a time domain) applied to the transform coefficients signaled in the data stream for the respective transform coded temporal block (e.g., by means of applying an inverse transform, like an inverse trigonometric transform, onto the transform coefficients).

The decoder 12 may be configured to decode the transform coefficients for the respective transform coded temporal block from the data stream 16 by decoding an end-sample position (e.g., an EndPos-indicator, indicating that transform coefficients with a larger position have a value of zero) from the data stream 16 and inferring that all transform coefficients of the respective transform coded temporal block following (e.g., from lower to higher frequencies) the end-sample-position along a transform coefficient coding order are zero (e.g., the transform coefficient coding order may be equal to the sample order within the respective transform coded temporal block).

The following embodiments particularly relate to scenario, in which a number of samples (e.g., K) within the template may be equal to or larger than a position of a residual sample within the temporal block (e.g., i being smaller than or equal to K). Such a scenario may particularly relate to a decoding of a first few residual samples. However, a distinction of such cases and various steps disclosed herein are optional.

The set of prediction modes may comprise a bypass prediction mode (e.g., generating a zero prediction signal, e.g., wherein all samples of the prediction signal have a value of zero) according to which the prediction signal 64 of the respective temporally residual-predicted temporal block 140 is set to zero (e.g., so that decoded residual samples become decoded samples of the digital time-varying signal 92),

The decoder 12 may be configured to, in the determining the prediction residual signal 80, check whether the selected prediction mode of the respective temporally residual-predicted temporal block 140 is the bypass prediction mode (e.g., based on a signaled index or bin sequence indicating the prediction mode).

If the selected prediction mode of the respective temporally residual-predicted temporal block 140 is the bypass prediction mode, the decoder 12 may be configured to sequentially decode, along the sample order 320, each of first residual samples 314 of the residual samples 310 of the respective temporally residual-predicted temporal block 140, which (i.e., the first residual samples 314), along the sample order 320, are closer to a block border 316 (e.g., wherein the block border 316 is located, along coding order 320, between a last sample or residual sample of a previously coded temporal block and a first sample or residual sample of the currently coded temporal block) of the respective temporally residual-predicted temporal block 140 than the predetermined number (e.g., K, e.g., wherein the first residual samples 314 have a rank or position that is smaller than K within the currently coded temporal block), by using the template 300 of the predetermined number (e.g., K) of sample positions preceding a respective first residual sample 330₂ (e.g., a currently decoded first residual sample 330₂ of the first residual samples 314, e.g., wherein other first residual samples 314 may be decoded in a similar way as exemplarily defined for the respective first residual sample 330₂) with deriving a residual sample prediction value

$$( e . g . , {\sum }_{l = 1}^{K} {a}_{l} \cdot y [ M + i - l ] ,$$

e.g., a weighted sum with coefficients aᵢ as weights) for the respective first residual sample 330₂ based on, for each sample position of the template 300, which lies beyond the block border 316 (e.g., within the previously coded temporal block), an already decoded sample (e.g., y[M+i−l] for l≥i, e.g., already coded samples when beyond the border, e.g., already decoded residual samples within the currently coded temporal block) of the digital time-varying signal 92 which is comprised by a temporal block preceding the respective temporally residual-predicted temporal block 140 and is positioned at the respective sample position.

The decoder 12 may further be configured to, for each sample position of the template 300, which lies within the respective temporally residual-predicted temporal block 140, an already decoded residual sample (e.g., y[M+i−l] for l<i, wherein y[M+1] to y[M+i−1] correspond to c[1] to c[i−1], if the bypass prediction mode is selected) which is comprised by the respective temporally residual-predicted temporal block 140 and is positioned at the respective sample position, decoding a correction value (e.g., d[i], e.g., second-stage-correction value 313) for the respective first residual sample 330₂ from the data stream 16, and correcting the residual sample prediction value using the correction value.

In other words, in case of a bypass prediction mode, a particular portion of the residual samples, namely first residual samples 314, for which the template 300 may extend into a previously decoded temporal block, the deriving of the residual sample prediction value may use already decoded samples values of the previously decoded temporal block for sample positions within the template 300 that extend over the previously decoded temporal block. Since the coding mode is a bypass prediction mode, the prediction signal may be zero, which means that the residual signal within the currently coded temporal block may be (or be similar to) the eventually decoded sample and therefore possibly be similar (e.g., in terms of amplitude and/or slope) to the decoded samples of the previously decoded temporal block. Due to the likely similarity, the first residual samples 314 of the currently coded temporal block and the decoded samples of the previously decoded temporal block may be used in the same template based step of deriving the residual sample prediction value.

For each sample position of the template 300, which lies beyond the block border 316 (e.g., within the previously decoded temporal bock), the respective already decoded sample (e.g., y[M+i−l] for l≥i) of the digital time-varying signal 92 may correspond to a prediction sample of the prediction signal 64 at the respective sample position within the temporal block preceding the respective temporally residual-predicted temporal block 140 corrected using a prediction residual sample of the prediction residual signal 80 at the respective sample position within the temporal block preceding the respective temporally residual-predicted temporal block 140.

The decoder 12 may be configured to, in the deriving the residual sample prediction value

$$( e . g . , {\sum }_{l = 1}^{K} {a}_{l} \cdot y [ M + i - l ] ) ,$$

perform a linear prediction based on already known sample values, one for each sample position of the template 300 and formed by an already decoded sample (e.g., y[M+i−l]) of the digital time-varying signal 92 which is comprised by a temporal block preceding the respective temporally residual-predicted temporal block 140 or an already decoded residual sample of the respective temporally residual-predicted temporal block 140 at the respective sample position.

The decoder 12 may be configured to, in the deriving the residual sample prediction value

$$( e . g . , {\sum }_{l = 1}^{K} {a}_{l} \cdot y [ M + i - l ] ) ,$$

form a weighted sum of addends (e.g., with addends y[M+i−l] summed up with weights aₗ), one for each sample position of the template and formed by an already decoded sample (e.g., y[M+i−l]) of the digital time-varying signal 92 which is comprised by a temporal block preceding the respective temporally residual-predicted temporal block 140 or an already decoded residual sample of the respective temporally residual-predicted temporal block 140 at the respective sample position.

For example, if all sample positions of the template lie beyond the block border 316 (e.g., when decoding in sample order 320 an earliest residual sample of the current temporal block 140), the decoder 12 may be configured to perform a linear prediction based on (e.g., form a weighted sum of) the already decoded samples (e.g., y[M+i−l]) of the digital time-varying signal 92 which are positioned at the sample positions of the template 300 within a temporal block preceding the respective temporally residual-predicted temporal block 140 (e.g., in sample order 320 the last K decoded samples thereof), or if not all sample positions of the template lie beyond the block border 316 (e.g., when decoding residual samples after the earliest residual sample of the current temporal block 140), the decoder 12 may be configured to perform a linear prediction based on (e.g., form a weighted sum of) the already decoded samples (e.g., y[M+i−l]) of the digital time-varying signal 92 which are positioned at the sample positions of the template 300, which lie beyond the block border 316 within a temporal block preceding the respective temporally residual-predicted temporal block 140, and the already decoded residual samples which are positioned at the sample positions of the template 300, which lie within the respective temporally residual-predicted temporal block 140.

The decoder 12 may be configured to, in the deriving the second-stage residual sample prediction value 311

$$( e . g . , {\sum }_{l = 1}^{K} {a}_{l} \cdot c [ i - l ] ) ,$$

form a weighted sum of the already decoded residual samples within the template (300), and configured to use, in the deriving the second-stage residual sample prediction value 311 and the deriving the residual sample prediction value, for each sample position, a weight which is commonly used for the deriving the second-stage residual sample prediction value and the deriving the residual sample prediction value, respectively. E.g., the decoder 12 may be configured to use at the deriving the second-stage residual sample prediction value the same weights as at the deriving the residual sample prediction value. For example, a number of weights used at the deriving the second-stage residual sample prediction value and at the deriving the residual sample prediction value, respectively, may be equal to the predetermined number of sample positions within the template. For example, the amount (e.g., an amount of K) of coefficients aₗ for deriving either of the second-stage residual sample prediction value and the residual sample prediction value may be the same, wherein as an option, the coefficients (or weights) aₗ may also be the same.

The decoder 12 may be configured to perform the decoding the correction value (e.g., d[i], e.g., in the same way as the second-stage-correction value 313) for the currently decoded first residual sample (330₂) from the data stream 16 using entropy decoding (or any versions thereof disclosed herein).

The decoder 12 may be configured to decode each of transform coded temporal blocks of the temporally residual-predicted temporal blocks 140 by deriving the correction value of the first residual samples 314 (e.g., in the sequentially decoding the first residual samples, deriving the correction value for the respective first residual sample) by means of a re-transformation (e.g., from a frequency domain to a time domain) applied to the transform coefficients signaled in the data stream 16 for the respective transform coded temporal block (e.g., by means of applying an inverse transform, like an inverse trigonometric transform, onto the transform coefficients. The decoder 12 may be configured to derive a number of the transform coefficients being equal to a number of the residual samples of the respective transform coded temporal block, e.g., wherein the residual samples may comprise second-stage-predicted residual samples and first residual samples.

The decoder 12 may be configured to decode the transform coefficients for the respective transform coded temporal block from the data stream 16 by decoding an end-sample position (e.g., an EndPos-indicator, indicating that transform coefficients with a larger position have a value of zero) from the data stream 16 and inferring that all transform coefficients of the respective transform coded temporal block following (e.g., having a higher or later position in scan order, e.g., from lower to higher frequencies) the end-sample-position along a transform coefficient coding order are zero (e.g., the transform coefficient coding order may be equal to the sample order within the respective transform coded temporal block).

The digital time-varying signal 92 may be a predetermined coded channel of coded channels representing a multi-channel digital signal (e.g., any multi-channel digital signal disclosed herein). The previously coded temporal block may be of the same channel as the currently coded temporal block.

The decoder 12 may be configured to, if the selected prediction mode of the respective temporally residual-predicted temporal block 140 is the bypass prediction mode, sequentially decode, along the sample order 320, each of the first residual samples 314 of the residual samples 310 of the respective temporally residual-predicted temporal block 140, with deriving a further residual sample prediction value

$$( e . g . , {\sum }_{j = 1}^{V} {b}_{j} {y}^{{c}_{j}} [ M - {t}_{j} + i ] )$$

for the respective first residual sample 330₂ based on a set of consecutive already decoded samples (e.g., y^{c}^{ⱼ}[M−tⱼ+i], e.g., a set of already decoded samples with consecutive sample positions within the further predetermined coded channel) of a further digital time-varying signal which is a further predetermined coded channel of the coded channels (e.g., different from the channel of the respective first residual sample 330₂), and correcting both the residual sample prediction value and the further residual sample prediction value using the correction value (e.g., by summing the residual sample prediction value, the further residual sample prediction value and the correction value).

The following embodiments particularly relate to an approach which may include extending the prediction signal. Any feature disclosed in the following may be combined with any other embodiment disclosed herein.

The set of prediction modes may comprise a bypass prediction mode according to which the prediction signal of the respective temporally residual-predicted temporal block 140 is set to zero (e.g., so that decoded residual samples become decoded samples of the digital time-varying signal 92), wherein the decoder is configured to, in the determining the prediction residual signal 80, check whether the selected prediction mode of the respective temporally residual-predicted temporal block 140 is the bypass prediction mode, if the selected prediction mode of the respective temporally residual-predicted temporal block 140 is not the bypass prediction mode, for each of a number of consecutive block sample positions within a temporal block preceding the respective temporally residual-predicted temporal block 140 from a block border 316 of the respective temporally residual-predicted temporal block 140, the number of consecutive block sample positions equaling the predetermined number (e.g., K) of sample positions, extend the prediction of the respective temporally residual-predicted temporal block 140 using the selected prediction mode onto the respective block sample position to obtain an extended prediction sample value (e.g., pred[1−l]) for the respective sample position, derive an artificial prediction residual sample value (e.g., c[i−l]) for the respective block sample position based on (so as to be representative of the prediction error of the extended prediction sample relative to the decoded sample (e.g., y[M−l]) of the digital time-varying signal 92 within a temporal block preceding the respective temporally residual-predicted temporal block 140) the extended prediction sample value for the respective block sample position and an already decoded sample (e.g., y[M−l]) of the digital time-varying signal 92 within a temporal block preceding the respective temporally residual-predicted temporal block 140 at the respective block sample position, and sequentially decode, along the sample order 320, each of first residual samples 314 of the residual samples 310 of the respective temporally residual-predicted temporal block 140, which (i.e., the first residual samples 314), along the sample order 320, are closer to a block border 316 of the respective temporally residual-predicted temporal block 140 than the predetermined number (e.g., K), by deriving a residual sample prediction value

$$( e . g . , {\sum }_{l = 1}^{K} {a}_{l} \cdot c [ i - l ] )$$

for the respective first residual sample 330₂ based on, for each sample position of the template 300, which lies beyond the block border 316, the artificial prediction residual sample value (e.g., c[i−l]) at the respective sample position and, for each sample position of the template 300, which lies within the respective temporally residual-predicted temporal block 140, an already decoded residual sample (e.g., c[i−l] for l<i) which is comprised by the respective temporally residual-predicted temporal block 140 and is positioned at the respective sample position, decoding a correction value (e.g., d[i]) for the respective first residual sample 330₂ from the data stream 16, and correcting the residual sample prediction value using the correction value.

In other words, the decoder 12 may “run out” of residual samples within the template 300 that belong to the currently coded temporal block 140, when predicting the residual sample prediction value. However, using directly the already decoded sample of the previously coded temporal block 140 instead of residual samples may yield a poor prediction, as the residual samples of the currently coded block 140 may have a different (e.g., smaller) value range than the already coded samples previously coded temporal block (e.g., as they may be formed by a sum of a prediction and a residual). The decoder 12 may be configured to derive artificial prediction residual sample value (e.g., substitute prediction residual values) based on extended prediction sample value (e.g., which may form a substitute prediction sample for the previously coded temporal block) and the already decoded samples of the previously coded temporal block. Therefore, the artificial prediction residual sample is likely to be in a similar value range as the prediction samples within the currently coded block (unlike already coded samples of the previously coded block), while also having a similar prediction behavior as the prediction signal 64 of the currently coded temporal block, which allows forming substitute residual samples that are similar to the residual sample values within the currently coded block. As a result, the residual sample prediction value determined based on the artificial prediction residual sample values and the already decoded residual sample may yield a better prediction.

The decoder 12 may be configured to derive the residual sample prediction value as described independent from checking whether the selected prediction mode of the respective temporally residual-predicted temporal block 140 is the bypass prediction mode.

In other words, the decoder 12 may be configured to, in the determining the prediction residual signal 80, for each of a number of consecutive block sample positions within a temporal block preceding the respective temporally residual-predicted temporal block 140 (e.g., currently coded block) from a block border 316 of the respective temporally residual-predicted temporal block 140, the number of consecutive block sample positions equaling the predetermined number (e.g., K) of sample positions, extend the prediction of the respective temporally residual-predicted temporal block 140 using the selected prediction mode onto the respective block sample position to obtain an extended prediction sample value (e.g., pred[1−l]) for the respective sample position, derive an artificial prediction residual sample value (e.g., c[i−l]) for the respective block sample position based on (e.g., so as to be representative of the prediction error of the extended prediction sample relative to the decoded sample, e.g., y[M−l], of the digital time-varying signal 92 within a temporal block preceding the respective temporally residual-predicted temporal block 140) the extended prediction sample value for the respective block sample position and an already decoded sample (e.g., y[M−l]) of the digital time-varying signal 92 within a temporal block preceding the respective temporally residual-predicted temporal block 140 at the respective block sample position, and sequentially decode, along the sample order 320, each of first residual samples 314 of the residual samples 310 of the respective temporally residual-predicted temporal block 140, which (i.e., the first residual samples 314), along the sample order 320, are closer to a block border 316 of the respective temporally residual-predicted temporal block 140 than the predetermined number (e.g., K), by deriving a residual sample prediction value

$$( e . g . , {\sum }_{l = 1}^{K} {a}_{l} \cdot c [ i - l ] )$$

for the respective first residual sample 330₂ based on, for each sample position of the template 300, which lies beyond the block border 316, the artificial prediction residual sample value (e.g., c[i−l]) at the respective sample position and, for each sample position of the template 300, which lies within the respective temporally residual-predicted temporal block 140, an already decoded residual sample (e.g., c[i−l] for l<i) which is comprised by the respective temporally residual-predicted temporal block 140 and is positioned at the respective sample position, decoding a correction value (e.g., d[i]) for the respective first residual sample 330₂ from the data stream 16, and correcting the residual sample prediction value using the correction value.

The following examples may be included independent form whether a checking of the selected prediction mode is performed, e.g., in either of the two embodiments described above, involving deriving the artificial prediction residual sample value).

The decoder 12 may be configured to, in the deriving the artificial prediction residual sample value (e.g., c[i−l]) for the respective block sample position, subtract (e.g., sample-wise) the extended prediction sample value for the respective block sample position from the already decoded sample (e.g., y[M−l]) of the digital time-varying signal 92 within the temporal block preceding the respective temporally residual-predicted temporal block 140 at the respective block sample position (e.g., c[i−l]-pred[1−l]). However, other linear combinations may be possible. The decoder 12 may be configured to derive all necessary extended prediction sample value once and reuse said values for deriving a residual sample prediction value

$$( e . g . , {\sum }_{l = 1}^{K} {a}_{l} \cdot c [ i - l ] )$$

for each of the respective first residual sample 330₂. For example, the decoder 12 may be configured to determine K extended prediction sample values based on the last (in sample order 320) K already decoded samples of the previously coded temporal block for a template 300 with K samples. The decoder 12 may subsequently use all K extended prediction samples values for a first sample (in sample order 320) of the first residual samples 314 and then K−1 extended prediction samples values (e.g., and one residual sample of the currently coded temporal block 140) for a second sample (in sample order 320) of the first residual samples (e.g., and continue the same pattern for the remaining first residual samples 314). Alternatively, the decoder 12 may be configured to newly determine extended prediction sample values for each one of the first residual samples.

For each of the number of (e.g., last K) consecutive block sample positions within the temporal block preceding the respective temporally residual-predicted temporal block 140 from the block border 316 of the respective temporally residual-predicted temporal block 140, the already decoded sample (e.g., y[M−l]) of the digital time-varying signal 92 within the temporal block preceding the respective temporally residual-predicted temporal block 140 at the respective block sample position may correspond to a prediction sample of the prediction signal 64 at the respective sample position within the temporal block preceding the respective temporally residual-predicted temporal block 140 corrected using a prediction residual sample of the prediction residual signal 80 at the respective sample position within the temporal block preceding the respective temporally residual-predicted temporal block 140. In other words, the already decoded samples themselves may also be decoded based on (or as) a prediction residual signal 64 (of the corresponding previous temporal block) corrected (e.g., linear combination, e.g., sample-wise) using a prediction residual signal 80 (of the corresponding previous temporal block).

The decoder 12 may be configured to, in the deriving the residual sample prediction value

$$( e . g . , {\sum }_{l = 1}^{K} {a}_{l} \cdot c [ i - l ] ) ,$$

perform a linear prediction (e.g., a sum in which each residual sample value has a power of one) based on, for each sample position of the template 300, which lies beyond the block border 316 (e.g., within the previously coded temporal block, e.g., which would lie in the previously coded block, but the artificial prediction residual sample values are used instead), the artificial prediction residual sample value (e.g., c[i−l]) at the respective sample position and, for each sample position of the template 300, which lies within the respective temporally residual-predicted temporal block 140 (e.g., to the right of the block border 316), an already decoded residual sample (e.g., c[i−l] for l<i) which is comprised by the respective temporally residual-predicted temporal block 140 and is positioned at the respective sample position.

The decoder 12 may be configured to, in the deriving the residual sample prediction value

$$( e . g . , {\sum }_{l = 1}^{K} {a}_{l} \cdot c [ i - l ] ) ,$$

form a weighted sum of addends (e.g., with addends c[i−l] and weights aₗ), one for each sample position of the template and formed by the artificial prediction residual sample value which is comprised by a temporal block preceding the respective temporally residual-predicted temporal block 140 or the already decoded residual sample of the respective temporally residual-predicted temporal block 140 at the respective sample position.

For example, the decoder 12 may be configured to, in the deriving the second-stage residual sample prediction value

$$( e . g . , {\sum }_{l = 1}^{K} {a}_{l} \cdot c [ i - l ] ) ,$$

form a weighted sum of the already decoded residual samples within the template 300, and may be configured to use, in the deriving the second-stage residual sample prediction value 313 (e.g., in case the entire template 300 is located within the currently coded temporal block 140) and the deriving the residual sample prediction value (e.g., in case the template 300 extends beyond the currently coded temporal block, e.g., using artificial prediction residual sample values, e.g., using previously coded samples in case of a bypass-prediction mode), for each sample position, a weight (e.g., aₗ) which is commonly used for the deriving the second-stage residual sample prediction value and the deriving the residual sample prediction value, respectively. For example, the decoder 12 may be configured to use at the deriving the second-stage residual sample prediction value 313 the same weights (e.g., aₗ) as at the deriving the residual sample prediction value. For example, a number of weights (e.g., K) used at the deriving the second-stage residual sample prediction value 313 and at the deriving the residual sample prediction value, respectively, may be equal to the predetermined number of sample positions within the template (e.g., wherein as an option, a number and value of weights aₗ). However, the weights may be different (e.g., one or more of weights may be lower for deriving the residual sample prediction value compared to deriving the second-stage residual sample prediction value 313) or a number of weights (e.g., a value K may) may be different (e.g., a smaller amount of weights may be used for deriving the residual samples prediction value).

The decoder 12 may be configured to, in the decoding the correction value (e.g., d[i]) for the respective first residual sample 330₂ from the data stream 16, use entropy decoding. For example, any entropy coding disclosed herein may be used.

The decoder 12 may be configured to decode each of transform coded temporal blocks (e.g., a block of coefficients, e.g., obtained by transforming a corresponding temporal block 140 into a transform domain, such as a frequency domain, wherein the transform coded block may contain coefficients that may be a different number or same number as samples of the corresponding temporal block 140) of the temporally residual-predicted temporal blocks 140 by deriving the correction value of the first residual samples 314 (e.g., in the sequentially decoding the first residual samples, deriving the correction value for the respective first residual sample) by means of a re-transformation applied to the transform coefficients signaled in the data stream for the respective transform coded temporal block (e.g., by means of applying an inverse transform, like an inverse trigonometric transform, onto the transform coefficients. For example, the decoder 12 may be configured to derive a number of the transform coefficients being equal to (or different, e.g., smaller than) a number of the residual samples of the respective transform coded temporal block, wherein the residual samples may comprise second-stage-predicted residual samples and first residual samples.

For example, the decoder 12 may be configured to decode the transform coefficients for the respective transform coded temporal block from the data stream 16 by decoding an end-sample position (e.g., an EndPos-indicator, indicating that transform coefficients with a larger position have a value of zero) from the data stream 16 and may infer that all transform coefficients of the respective transform coded temporal block following the end-sample-position along a transform coefficient coding order (e.g., from lower to higher frequencies) are zero (e.g., the transform coefficient coding order may be equal to the sample order within the respective transform coded temporal block).

Generally, for any residual sample 310 the second-stage-correction value 313 or the correction value (e.g., for first residual samples 314, e.g., in case of a bypass-prediction mode, e.g., in case of no bypass-prediction mode) may be coded in form of transform coded temporal blocks. For example, any of the correction values may be transformed by the encoder 10 into a transform coded temporal block and re-transformed by the decoder 12 into the correction values.

The following embodiments particularly relate to an approach which may include decoding the residual value without prediction. Any feature disclosed in the following may be combined with any other embodiment disclosed herein.

The set of prediction modes may comprise a bypass prediction mode (e.g., any bypass prediction mode disclosed herein) according to which the prediction signal of the respective temporally residual-predicted temporal block is set to zero (e.g., so that decoded residual samples become decoded samples of the digital time-varying signal), wherein the decoder 12 may be configured to, in the determining the prediction residual signal 80, check whether the selected prediction mode of the respective temporally residual-predicted temporal block 140 is the bypass prediction mode.

The decoder 12 may be configured to, if the selected prediction mode of the respective temporally residual-predicted temporal block 140 is not the bypass prediction mode, decode first residual samples 314 of the residual samples 310 of the respective temporally residual-predicted temporal block 140, which (i.e., the first residual samples 314), along the sample order 320, are closer to a block border 316 of the respective temporally residual-predicted temporal block 140 than the predetermined number (e.g., K), without using the template (e.g., unpredictively, e.g. decoding the first residual samples 314 directly from the data stream, e.g., without correcting same and/or without using prediction).

In other words, the decoder 12 may be configured to decode values for the first residual samples 314 (e.g., samples with a position smaller than or equal to K) without a second-stage prediction, e.g., only a first-stage prediction, wherein the decoded value for a first residual sample 314 forms a value of the prediction residual signal 80.

The decoder 12 may be configured to, in the determining the prediction residual signal 80, decode first residual samples 314 of the residual samples 310 of the respective temporally residual-predicted temporal block 140, which (i.e., the first residual samples 314), along the sample order 320, are closer to a block border 316 of the respective temporally residual-predicted temporal block 140 than the predetermined number (e.g., K), without using the template (e.g., unpredictively, e.g. decoding the first residual samples directly from the data stream, e.g., without correcting same and/or without using prediction).

The decoder may be configured to, in the decoding the the first residual samples 314 of the residual samples 310 of the respective temporally residual-predicted temporal block 140 from the data stream 16, use entropy decoding (e.g., any entropy coding disclosed herein).

The decoder 12 may be configured to, in the decoding the second-stage-correction value 313 (e.g., d[i]) for the currently decoded second-stage-predicted residual sample 330₁ from the data stream 16, use entropy decoding, wherein the decoder may be configured to use a first set of one or more context models in the decoding the first residual samples 314 and a second set of one or more context models in the decoding the second-stage-correction value 313. The first residual samples 314 may have a different value range than the second-stage-correction value 313 (e.g., due to a potential lack of a prediction). Therefore, the first and second sets may be selected differently, wherein a different set of context models may allow adjusting the context models better to a value statistic of the first residual samples 314 and the second-stage-correction value 313, respectively.

For example, the first set of one or more context models may be different from the second set of one or more context models.

The decoder 12 may be configured to decode the first residual samples 314 and the second-stage-correction value 313 for the currently decoded second-stage-predicted residual sample 330₁ using a binarization which may comprise a significance bin and one or more greater-x-flags (e.g., wherein a greater-x-flag may indicate that an overall value of the binarization has a value greater than x, e.g., a greater-3-flag may indicate that the overall value is greater than 3), and to use the first and second set of one or more context models to entropy code the significance bin and the one or more greater-x-flags.

The decoder 12 may be configured to decode each of transform coded temporal blocks of the temporally residual-predicted temporal blocks 140 by deriving the first residual samples 314 by means of a re-transformation (e.g., T⁻¹) applied to the transform coefficients signaled in the data stream 16 for the respective transform coded temporal block (e.g., by means of applying an inverse transform, like an inverse trigonometric transform, onto the transform coefficients). The decoder 12 may be configured to derive a number of the transform coefficients being equal to a number of the residual samples of the respective transform coded temporal block, wherein the residual samples may comprise second-stage-predicted residual samples and first residual samples).

The decoder 12 may be configured to decode the transform coefficients for the respective transform coded temporal block from the data stream 16 by decoding an end-sample position (e.g., any end-sample position described herein) from the data stream 16 and inferring that all transform coefficients of the respective transform coded temporal block following the end-sample-position along a transform coefficient coding order are zero (the transform coefficient coding order may be equal to the sample order within the respective transform coded temporal block).

The encoder 10 (e.g., as shown in FIG. 1B) may be configured to perform any corresponding step and/or comprise any corresponding feature as disclosed herein with reference to any decoder 12.

Further is provided a method for decoding a digital time-varying signal 92 from a data stream 16. The method comprises decoding the digital time-varying signal 92 from the data stream 16 in temporal blocks by decoding each temporally residual-predicted temporal block 140 of the digital time-varying signal 92 by predicting the respective temporally residual-predicted temporal block 140 using a selected prediction mode out of a set of prediction modes to obtain a prediction signal 64, determining a prediction residual signal 80 of the respective temporally residual-predicted temporal block 140, and correcting the prediction signal 64 using the prediction residual signal 80, wherein, in the determining the prediction residual signal 80, sequentially decode second-stage-predicted residual samples 312 of residual samples 310 of the respective temporally residual-predicted temporal block 140 along a sample order 320 by deriving a second-stage residual sample prediction value

$$( e . g . , {\sum }_{l = 1}^{K} {a}_{l} \cdot c [ i - l ] )$$

for a currently decoded second-stage-predicted residual sample 330₁ based on already decoded residual samples within a template 300 of a predetermined number (e.g., K) of sample positions preceding the currently decoded second-stage-predicted residual sample 330₁ in sample order 320, decoding a second-stage-correction value e.g., d[i]) for the currently decoded second-stage-predicted residual sample 330₁ from the data stream 16, and correcting the second-stage residual sample prediction value using the second-stage-correction value.

The method for decoding may comprise any step and/or functionality described herein with reference to the decoder 12 (e.g., performed by the decoder).

Further is provided a method for encoding a digital time-varying signal 92 into a data stream 16. The method may comprise encoding the digital time-varying signal 92 into the data stream 16 in temporal blocks by encoding each temporally residual-predicted temporal block 140 of the digital time-varying signal 92 by predicting the respective temporally residual-predicted temporal block 140 using a selected prediction mode out of a set of prediction modes to obtain a prediction signal 64, and determining a prediction residual signal 80 of the respective temporally residual-predicted temporal block 140 wherein, in the determining the prediction residual signal 80, sequentially encode second-stage-predicted residual samples 312 of residual samples 310 of the respective temporally residual-predicted temporal block 140 along a sample order 320 by deriving a second-stage residual sample prediction value

$$( e . g . , {\sum }_{l = 1}^{K} {a}_{l} \cdot c [ i - l ] )$$

for a currently encoded second-stage-predicted residual sample 330₁ based on already encoded residual samples within a template 300 of a predetermined number (e.g., K) of sample positions preceding the currently encoded second-stage-predicted residual sample 330₁ in sample order 320, encoding a second-stage-correction value (e.g., d[i]) for the currently encoded second-stage-predicted residual sample 330₁ into the data stream 16.

The method for encoding may comprise any step and/or functionality described herein with reference to the encoder 10 (e.g., performed by the encoder 10).

Further is provided a computer program product (or computer program) for implementing any method of encoding and/or decoding described herein when being executed on a computer or signal processor. The computer program product may be stored on a storage medium such as a transitory storage medium (e.g., any data storage disclosed herein, e.g., hard drive, USB stick, server, a server system, a storage of a cloud system, or compact disc).

Further is provided a data stream encoded (e.g., generated) by any encoding method disclosed herein. The data stream may be stored on a data storage, e.g., a non-transitory storage medium (e.g., any data storage disclosed herein).

### 1 Setup

The present disclosure deals with the coding of digital time-varying signal such as a biomedical waveform data, for example, possibly having multiple channels. Let y[1], . . . , y[M] denote already reconstructed samples (e.g., with sample values y and index 1 to M, wherein M may measure samples from a beginning of the digital time-varying signal or any other previous time), which are located before the current samples in a temporal way (e.g., temporally before a temporal block 140 to be coded). Let N be a block-length (e.g., amount of samples within a temporal block 140). Assume that the reconstructed sample y[M+1], . . . , y[M+N] are to be generated for the current block (e.g., temporal block 140, e.g., having a length N). Let pred[1], . . . , pred[N] denote the values of the prediction signal (e.g., samples of the prediction signal 64). In this disclosure, the following block based prediction modes may be supported (e.g., wherein the set of prediction modes may comprise the modes disclosed herein in any combination, e.g., wherein the set may be predefined and/or depend on the block size N), wherein for each block (or a subset of the blocks), all or some of the below prediction modes may be used (e.g., but where only one prediction mode is used per block) and wherein the selection of the prediction mode to be used may be signalled in the bitstream:
1. A DC- or mean-prediction mode (e.g., DC prediction mode),
2. A half-slope prediction mode (e.g., a linear prediction mode of one or more linear prediction modes),
3. A quarter-slope prediction mode (e.g., a linear prediction mode of one or more linear prediction modes),
4. A prediction mode using signalled temporal offsets that generate a prediction signal out of already decoded samples of the same channel (e.g., block-copy prediction mode),
5. A prediction mode which generates no prediction, i.e. the zero prediction signal (e.g., bypass prediction mode), or
6. A prediction mode which generates a prediction signal out of multiple portions of already decoded blocks of channels different from the current channel, possibly with temporal alignment (e.g., cross-channel prediction mode). For example, the prediction signal may be generated by using one scale parameter per reference channel and/or one offset value. One or more of the number of channels to use, the channel indices and the temporal offsets per channel may be signalled in the bitstream. The scale parameters and/or the offset value might be generated by minimizing the prediction error on reconstructed samples that immediately proceed the current block and/or they may be signalled in the bitstream (e.g., one or more of scale parameters and offset value may be signaled).

### 2 Sample-Wise Transforms

In this disclosure, block-based transform coding of the corresponding prediction residuals may be supported, e.g., advantageously with using a discrete cosine transform or a discrete sine transform. However, it may be also supported to not use such a block-based transform but rather, for example, use a ‘sample-wise transform’ of the prediction residuals. In this disclosure, it may be indicated in the bitstream (e.g., using a flag) whether the block-based transform or the sample-wise transform is used. In the following, the case is described where the ‘sample-wise transform’ is to be used. However, any disclosure herein may also be applied to a block-based transform.

First, a number K, the transform length (e.g., predetermined number of sample positions within the template 300), may be specified for the current block. For example, the number K may be signalled in the bit-stream (e.g., for each temporal block, for a set of temporal blocks, e.g., when the number K changes within the bit stream 16). Moreover, for the given number K, coefficients a₁, . . . , a_{K} may be available at the decoder for the current block. The coefficients can, for example be signalled in the bitstream or can form one set of coefficients out of a predefined set of sets of coefficients, for example, wherein an index to the set may be signalled in the bitstream. Then, the decoder proceeds, for example, sequentially to generate reconstructed residual samples c[1], . . . , c[N] (e.g., samples of the prediction residual signal 80) on the given block, e.g., the decoder may generate a reconstructed residual sample c[i] (e.g., with i forming an index between 1 and N) based on already reconstructed residual samples c[1], . . . , c[i−1] (e.g., a subset thereof, e.g., K samples of the prediction residual signal 80), the coefficients {a₁, . . . , a_{K}} and a residual value d[i] (e.g., second-stage correction value 313) that is transmitted in the bit-stream, for example, by entropy coding methods, for example, using a context coded significance flag, for example, as well as a truncated unary coding of a first part, for example a Rice coding of a remainder, and, for example, an exponential Golomb coding of a second remainder. Some of the coded bins may be context coded using context based adaptive binary arithmetic coding (CABAC).

For example, having decoded the residual samples c[i], the decoder may generate the reconstructed samples as
y[M+i]=c[i]+pred[i], 1≤i≤N.

In other words, the correcting the prediction signal 64 is corrected using the prediction residual signal 80, e.g., by a sample wise addition.

In order to describe the way in which the residual sample value c[i] is generated, in this disclosure, as one of its inventive methods, it is argued that one may, for example, differentiate the cases i>K and the case i≤K and that particularly for the case i≤K dedicated methods are presented here. A differentiation of the cases is optional, and, in case of differentiation, the decoder 12 and/or encoder 10 may be configured perform adapted methods for one or both of the cases.

The Case of a Position i>K

Assume that the reconstructed residual sample c[i] is to be generated at the decoder at position i>K (e.g. the preceding K samples within the template 300 are within the residual prediction residual signal 80 of the same temporal block 140, e.g., not of two different temporal blocks 140). For example, by the sequential structure, it may be assumed that the reconstructed residual sample values c[1], . . . , c[i−1] have already been generated and are available at the decoder. Then the decoder may decode a coefficients value d[i] (e.g., second-stage-correction value 313) from the bit-stream by means of entropy decoding as disclosed herein. Having decoded d[i], the decoder may put

$$c [ i ] = d [ i ] + {\sum }_{l = 1}^{K} {a}_{l} \cdot c [ i - l ] \qquad ( 1 )$$

For example, the decoder 12 may be configured to perform a linear prediction (e.g., based on a sum, in which the samples values of the already decoded residual samples within the template 300 are parts of a sum at a power of one) based on the already decoded residual samples within the tem-plate 300. The decoder 12 may be configured to form a weighted sum of the already decoded residual samples (e.g., with coefficients {a₁, . . . , a_{K}} as weights).

The Case of a Position i≤K

If i≤K, a direct generalization of (1) may not be a priori straight forward since the sample values c[i−l] may not be available if l≥i (e.g., samples of the prediction residual signal 80 may not be available within the same temporal block 140). For example, only the already reconstructed sample values y[M+i−l] (e.g., reconstructed sample values of a temporal block 140 preceding the temporal block 140 to be deoced) may be available at the decoder.

However, for example, if the prediction mode is not the zero prediction mode (e.g., bypass prediction mode), the sample values y[M−K+1], . . . , y[M] and the values c[1], . . . , c[i−1] may represent different type of content: y[M−K+1], . . . , y[M] represents already reconstructed sample values (e.g., completely reconstructed samples of a temporal block) while c[1], . . . , c[i−1] represent residual values (e.g., samples of the prediction residual signal 80) between the prediction values p[1], . . . , p[i−1] (e.g., samples of the prediction signal 64) and the reconstruction values y[M+1], . . . , y[M+i−1]. Moreover, it may be assumed (or likely) that the weights aₗ (or coefficients), e.g., occurring in equation (1) above, e.g., are rather designed to handle residual inputs (e.g., in particular due to the fact that, since N may be quite large in comparison to K there may be typically much more sample locations i with 1≤i≤N which may satisfy i>K than sample locations which may satisfy i≤K).

Thus, in this disclosure, it is proposed to, for example, differentiate the generation of c[i] for i≤K depending on the prediction mode that is used. For example, if the zero prediction mode (e.g., bypass prediction mode) is used on the current block, it is proposed to simply put, for example,

$$c [ i ] = d [ i ] + {\sum }_{l = 1}^{K} {a}_{l} \cdot y [ M + i - l ] . \qquad ( 2 )$$

For example, the decoder 12 may be configured to check whether the selected prediction mode of the respective temporally residual-predicted temporal block 140 is the bypass prediction mode. If the selected prediction mode of the respective temporally residual-predicted temporal block 140 is the bypass prediction mode, the decoder 12 may be configured to sequentially decode, along the sample order 320, each of first residual samples 314 of the residual samples 310 of the respective temporally residual-predicted temporal block 140, which (e.g., the first residual samples 314), along the sample order 320, are closer to a block border 316 of the respective temporally residual-predicted temporal block 140 than the predetermined number (e.g., K, e.g., a sequence of K samples of the temporal block 140 that extends from the block border 316 to a Kth sample, e.g., wherein said K samples are decoded in the following described way, e.g., wherein subsequent samples that follow the K samples may be decoded differently), by using the template 300 of the predetermined number (e.g., K) of sample positions preceding the respective first residual sample 330₂ (e.g., a currently decoded residual samples 330₂, e.g., for which the following steps are described representative for all the first residual samples 314 being decoded) with deriving a residual sample prediction value

$$( e . g . , {\sum }_{l = 1}^{K} {a}_{l} \cdot y [ M + i - l ] ,$$

e.g., a linear predication based on already decoded samples within the template, e.g., based on or as a weighted sum of already decoded residual samples) for the respective first residual sample 330₂ based on, for each sample position of the template 300, which lies beyond the block border 316 (e.g., not within the current temporal block 140, e.g., within a previously decoded temporal block, e.g., of the same channel), an already decoded sample (e.g., y[M+i−l] for l>i, e.g, for l=i to l=K, e.g., for the temporally last (K−i) samples of the previously coded temporal block) of the digital time-varying signal 92 which is comprised by a temporal block preceding the respective temporally residual-predicted temporal block 140 and is positioned at the respective sample position, and, for each sample position of the template 300, which lies within the respective temporally residual-predicted temporal block 140, an already decoded residual sample (e.g., y[M+i−l] for l<i, wherein y[M+1] to y[M+i−1] correspond to c[1] to c[i−1], if the bypass prediction mode is selected) which is comprised by the respective temporally residual-predicted temporal block 140 and is positioned at the respective sample position, decoding a correction value (e.g., d[i], e.g., second-stage residual sample prediction value 311) for the respective first residual sample 330₂ from the data stream 16, and correcting the residual sample prediction value using the correction value.

However, if the zero prediction mode is not used, in one inventive solution of the present application, it is proposed, for example, to extend the prediction generation to the temporally adjacent but previous locations M, M−1, . . . , M−K+1 (e.g., to obtain an extended prediction sample value). Here, the same prediction mode, for example, may be used for the current block. This means that, for example, for the case of the inter-channel prediction, the same linear-prediction method to generate prediction sample values out of (e.g., possibly temporarily shifted) reconstructed sample values of channels different to the current channels may be used also on the sample locations M, M−1, . . . , M−K+1 (e.g., or any other prediction mode selected for the currently coded temporal block may be used for the previously coded temporal block). It also means that, for example, for the prediction generation with temporal offsets (e.g., block-copy prediction mode), the same method as used for the current block may be applied to generate the artificial prediction values (e.g., artificial prediction residual sample value) as a possible superposition of already decoded sample values using, for example, the same temporal offsets as used for the current block. This method may yield ‘artificial’ or ‘extended’ prediction signal values pred[1−l] (e.g., extended prediction sample value) at the sample locations M+1−l, 1≤l≤K. Having generated these artificial prediction values, it is then, for example, proposed to define values

c[1−l]:=y[M]−pred[1−l], 1≤l≤K (3)

for example, before a sequential generation

c[1]→c[2]→ . . . →c[N]

of the actual residual values starts (e.g., before block order 316) and, for example, to then proceed as in the case i>K (e.g., with residual values within the currently coded temporal block). Thus, if the values c[1−l] are computed at the decoder as in (3) (e.g., or any other approach for deriving artificial prediction residual sample values), it is proposed, for example, to put

$$c [ i ] = d [ i ] + {\sum }_{l = 1}^{K} {a}_{l} \cdot c [ i - l ] \qquad ( 4 )$$

also for the case 1≤i≤K.

In another inventive solution, it is proposed to, for example, for the case that the zero prediction is not used (e.g., a bypass-prediction mode is not selected) and that 1 Si SK, completely disable the sum-part of (4) which is based on the a (e.g., without using the template, e.g., unpredictively, e.g., decoding first residual samples directly from the data stream, e.g., without correcting same and/or without using prediction). Thus, it is proposed to put, for example,

c[i]=d[i], ∀1≤i≤K (5)

in this case. However, this may lead to the fact that the d[i] for 1≤i≤K (e.g., for first residual samples 314) may statistically behave different to the d[i] for i>K (since for them, the process to predict c[i] further is disabled), in particular, one might expect that the magnitude of the d[i] for 1≤i≤K may be larger than the magnitude of the d[i] for i>K. Therefore, in the second inventive solution that uses (5), it is proposed to, for example, use a separate set of context models (e.g., a first and second context model) when coding the d[i] for 1≤i≤K than when coding them for i>K. This holds, for example, for the sig-flags and greater flags (e.g., greater-x-flags) used, for example, in the entropy coding of the general d[i].

### 3 Further Embodiment: Combination of Sample-Wise Transform and Block-Based Trigonometric Transform

In a different embodiment, it is proposed to combine the process of a sample-wise transform (in this section to be denoted as sample-wise secondary prediction/filtering) as specified above and a block-based trigonometric transform (for example the DCT-II or the DST-VII or the DST-II, e.g., or any other form of re-transformation) where, for example, the selection of the transform might either be implicit on the block-shape and/or prediction mode (e.g., a transformation and re-transformation is predetermined, e.g., by defining only one type of transformation, e.g., by providing a plurality of transformation types, wherein the decoder is able to derive the type of transformation based on decoded payload, e.g., based on one or more of a selected prediction mode, a block size, and a block shape) or where the selection of the transform is signalled in the bit-stream (e.g., as overhead, e.g., not implicitly in the payload). Thus, in the embodiment of the present section, such a combination shall be, exemplarily, explicitly signalled in the bit-stream (however, any description related to transformation may also be applied to embodiments without explicit signaling, but implicit signaling, e.g., derivable from a payload). If the combination is supported, using the notation of the previous section, the decoder first reconstructs the values d[i] (e.g., second-stage correction values 313, e.g., correction values for first residual samples of first residual samples) by decoding a set of trigonometric transform coefficients f[i], 1≤i≤N for the whole block of length N (e.g., wherein a number of transform coefficients N may be equal to a number N of samples values of the corresponding temporal block, e.g., wherein the number of transform coefficients N may be different from the number N of sample values of the corresponding temporal block, e.g., smaller or equal, e.g., N_{coefficients}≤Nₛₐₘₚₗₑₛ) by entropy-decoding with a method that, among other things, may use a dedicated syntax element endpos (e.g., end-sample position) with 1<endpos≤N+1, which may indicate that all trigonometric transform coefficients f[i] are zero if i<endpos and by then applying the inverse trigonometric transform to the f[i] (e.g., only to the coefficients up to the last non-zero coefficient indicated by endpos) to generate the d[i]. Having reconstructed the d[i] (e.g., deriving correction values by means of a re-transformation), the decoder may proceed with first generating, for example, ‘artificial residual samples’ (e.g., artificial prediction residual sample value), for example, c[0], . . . , c[−K+1] as in (3), e.g., with K as in the previous section (e.g., with filter 300 covering K samples positions), and then may generate the c[1], . . . , c[N] in the sequential manner, for example, as above using values a₁, . . . , a_{K} as above by inferring the analog of (1) resp. (4).

### 4 Further Embodiment: Sample-Wise Transform that Also Uses Sample Values from One or More Other Channels

In a further embodiment, it is proposed to additionally incorporate, for example, sample values from one or more already reconstructed portions of a signal which belong to channels that are different from the current channel (e.g., a channel that comprises the currently coded temporal block 140) to be reconstructed (e.g., using a cross-channel prediction mode). It is proposed, for example, to signal this extra option in the bitstream (e.g., wherein the set of prediction modes may comprise the cross-channel prediction mode, wherein the selection of the cross-channel prediction mode may be signaled), wherein it is also proposed that this option, for example, is exclusive with all of the options of prediction generation mentioned above except the zero prediction mode (e.g., wherein the cross-channel prediction mode is only combinable for the same temporal block with the bypass prediction mode and no other prediction mode) and thus, that a flag (or any other indicator) indicating whether this option (e.g., cross-channel prediction mode) is to be used for a current block (e.g., temporal block 140) or not is only transmitted/decoded, for example, if the zero prediction mode (e.g., bypass prediction mode) is used and else inferred to be false. In other words, when using other prediction modes (e.g., block-copy prediction mode or DC prediction mode), no use of the cross-channel prediction mode is implied an no indicator (e.g., flag) on whether the cross-channel prediction mode is to be used may need to be coded/signaled, wherein in the case of bypass prediction mode (which may be combinable with the cross-channel prediction mode) is selected, a flag may be coded/signaled, which indicates whether (in addition to the bypass prediction mode) the cross-channel prediction mode is selected. However, the exclusivity is optional and different combinations of prediction modes may be used.

In the case that the flag indicating that the option of the present section is to be used is true (e.g., that cross-channel prediction mode is selected, e.g., optionally with the bypass prediction mode), it is proposed that a number V (e.g., indicating an amount of channels other than the current channel is used for cross-channel prediction, e.g., V=2 if prediction from two channels other than the current channel is performed) and channel indices c₁, . . . , c_{V} (e.g., indicating an absolute channel index or a channel offset, e.g., if there are a total of 32 channels and channel with indices 4 and 13 are to be used for cross-channel prediction, absolute channel indices may be c₁=4 and c₂=13) that point to channels different from the current channel as well as optionally numbers b₁, . . . , b_{V} (e.g., indicating a weight for each channel) and optional temporal offsets t₁, . . . , t_{V} (e.g., indicating a temporal offset relative to the current temporal block, e.g., relative to the current temporal block or relative to a position relative to the current temporal block, e.g., relative to a first sample of the current temporal block, e.g., relative to N sample positions temporally before the first sample of the current temporal block or any number other than N), which may be provided such that, for example, tⱼ points into already reconstructed temporal positions of the channels cⱼ, are decoded from the bitstream so that, for example, analogously to (2)

$$( e . g . , which defines c [ i ] = d [ i ] + {\sum }_{l = 1}^{K} {a}_{l} \cdot y [ M + i - l ] )$$

and using d[i] to have the same meaning as above, one may put

$$c [ i ] = d [ i ] + {\sum }_{l = 1}^{K} {a}_{l} \cdot y [ M + i - l ] + {\sum }_{j = 1}^{V} {b}_{j} {y}^{{c}_{j}} [ M - {t}_{j} + i ] ,$$

$$1 \leq i \leq N .$$

Here, y^{c}^{ⱼ}[M−tⱼ+i] denotes the reconstructed sample value of channel cⱼ at sample position M−tⱼ+i. The values aₗ, bⱼ (e.g., one or both of aₗ and bⱼ) might, for example, also belong to a predefined set of sets of such coefficients, for example, in which case only an index which may point to the specific set within the set of set is decoded from the bitstream (e.g., an index pointing to a set of weights for channels and/or an index pointing to a set of weights for residual samples). In a special case, it is proposed that the value V may be inferred to be 1, the value c₁ may be inferred to point to the directly previous channel and the temporal offset t₁ may be inferred to be zero (e.g., if the current channel has a channel ID of 17, for V=1, it may be inferred that a channel with ID of 16 is to be referenced for the prediction, wherein, as an option, it may be further inferred that no temporal offset is used, e.g., a first sample in the referenced temporal block in channel ID 16 is located at the same time instance as a first sample in the currently coded temporal block 14).

In an extension (e.g., in one option), it is proposed to also additionally receive from the bitstream values ρⱼ (e.g., a channel decoding progress indicator) for each j=1, . . . , M (e.g., j=1 to V with V channels) which may be provided such such that for all 1≤q≤ρⱼ, tⱼ+q points to a temporal position such that in the channel cⱼ, the sample value y^{c}^{ⱼ}[M−tⱼ+i+q] has already been reconstructed for all 1≤i≤N. In this case, it is proposed that coefficients
{b_{j,1}, . . . , b_{j,ρj}:1≤j≤V}
   may be received from the bit-stream, e.g., in a manner similar to the method in which the reception of the b₁, . . . , bⱼ was described, so that analogously to (2) one may put

$$c [ i ] = d [ i ] + {\sum }_{l = 1}^{K} {a}_{l} \cdot y [ M + i - l ] + {\sum }_{j = 1}^{V} {\sum }_{q = 1}^{{ρ}_{j}} {b}_{j , q} {y}^{{c}_{j}} [ M - {t}_{j} + i + q ] ,$$

$$1 \leq i \leq N .$$

### 5 Further Embodiments

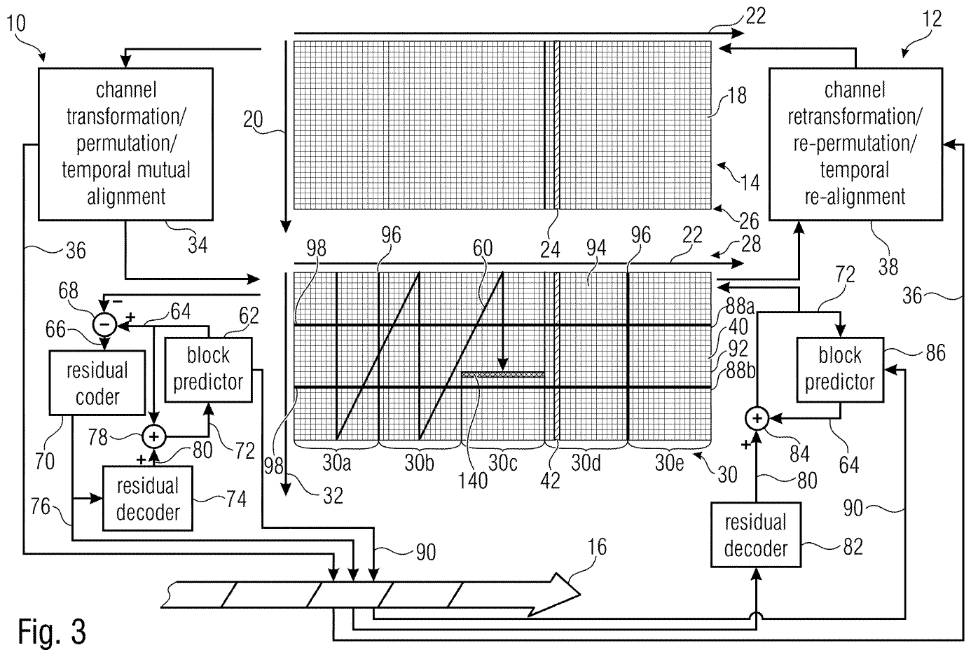

The above description is extended in the following by the presentation of further embodiments. Before this, however, the description proceeds with a presentation of a possible framework or codec into which the embodiments described above as well as the embodiments described further below may be built into. Many details described in this framework are, however, optional when being combined with any of the above or subsequently described embodiments. To be more precise, the framework is described with respect to FIG. 3 which shows an encoder for encoding a multi-channel digital signal 14 into a datastream 16 as well as decoder 12 for decoding the multi-channel digital signal 14 from datastream 16. This description of FIG. 3 shall be seen as a presentation of new embodiments of the present application which result when combining any of the embodiments described above or any of the embodiments described subsequently is combined with the decoder 12 or encoder 10 of FIG. 3 either by adopting all details/functionalities described with respect to FIG. 3 or with leaving-out some of the details/functionalities described with respect to FIG. 3. Sometimes such “optional” features of FIG. 3 are explicitly identified as being optional with respect to the combination of the previously and subsequently described embodiments, but the just-mentioned possible combinations of the previously/subsequently explained embodiments with the description of FIG. 3 shall not be restricted to the these explicitly identified variations of FIG. 3 in terms of leaving-out certain features.

In FIG. 3, the multi-channel digital signal 14 is illustrated by way of an array of samples with the samples being illustrated as small squares 18. Each line/row corresponds to a certain channel of the multi-channel digital signal 14. Each channel of signal 14 may have associated therewith a respective channel ID and FIG. 3 shows these channels as being ordered according to their channel ID along vertical axis 20 which, thus, corresponds to a “source” channel axis 20. The horizontal axis 22 corresponds to time so that samples 18 forming one column, or being horizontally aligned, are samples belonging to one common time instant. Such set/column of temporally co-located samples 18 is illustrated in FIG. 3 at 24.

Each channel, thus, forms a digital time-varying signal or time/amplitude or time-to-amplitude signal. The multi-channel digital signal m might have been obtained by at least one of Electrocardiography, Electroencephalography, Electromyography or seismic measurement. Differently speaking, the multi-channel digital signal might be a bio-physiological waveform data such as an electroencephalography (EEG) signal, an electrocardiogram (ECG), or an electromyography (EMG) signal, or seismic waveform data. However, each channel/signal might alternatively be another sort of waveform signal data such as scalar media data such as an audio signal and the signal 14 might be a multi-channel audio signal.

FIG. 3 illustrates the option according to which signal 14 is not coded directly, i.e., in the original domain 26, but in a so-called “coded domain” 28 which might differ from the original domain 26 by one or more of 1) channel transformation, 2) channel permutation and 3) temporal mutual channel alignment. The channel transformation, if applied, transforms, per sample time instant, a set or column 24 of samples from domain 26 to domain 28. Thus, in domain 28, the sample pitch and the time axis is the same as in domain 26, but the meaning of the channels is different, i.e., the “source” channels of domain 26 become transformed channels in domain 28. Accordingly, the vertical axis in FIG. 3 for domain 28 is denoted as 32. Note that the channel transformation might leave the number of channels unchanged so that there is the same number of channels in domain 26 as well as domain 28, but different approaches are also possible. Generally, the channel transformation would aim at reducing redundancy and trying to condense the channels' energy onto a fewer number of channels in domain 28. As said, the channel transformation is optional. Accordingly, in general terms, the channels in domain 28 are called “coded channels” in order to distinguish them from the “original” or “source” channels of digital signal 14 in domain 26. The permutation is also optional and may be used in combination with, or without, the channel transformation. If used in combination with the channel transformation, the permutation may be performed prior to and/or or subsequent to the channel transformation in order to permute/sort the source channels prior to transformation and the coded channels subsequent to the channel transformation. The channel transformation might be a DCT, DST, FFT or any other transformation. The temporal mutual alignment is also optional and might be seen as a constant temporal alignment between the source channels or the coded channels.

The module in encoder 10 performing the one or more of channel transformation, channel permutation and temporal mutual alignment is indicated in FIG. 3 as block 34. Side information 36 might be used in order to signal information on one or more of the following: 1) The channel transformation used, 2) information on the permutation(s) among the source channels and/or coded channels and 3) information on the mutual temporal alignment/delays between the source channels or coded channels wherein the temporal mutual alignment might be restricted to full sample precision. A corresponding block 38 in decoder 12 performs the reverse step, i.e., performs one or more of: 1) a channel retransformation, 2) a re-permutation of the source channels and/or coded channels and 3) a temporal re-alignment of the source channels or coded channels. Note, that if no channel transformation takes place, the coded channels are, in fact, equal to the source channels except for being temporally mutually aligned or being differently sorted due to permutation. Block 38 might be controlled by the before-mentioned side information 36.

Thus, the “actual coding” relates to the coded channels in domain 28. In the coded domain 28, the coded channels are depicted in FIG. 3 as lines or rows of samples 40, each extending along time axis 22, the coded channels being depicted one on top of the other along coded channel axis 32—potentially ordered according to a coded channel ID the have associated therewith—so as to result into an array of samples 40. Again, although FIG. 3 depicts the case that the number of source channels equals the number of coded channels, the number might be different. Further, if channel transformation is used, while there is no longer a clear association between source channels on the one hand and coded channels on the other hand, the temporal association remains: For each temporally co-located samples 24, there is a corresponding temporally co-located set 42 of samples 40 of the coded channels, wherein the set 42 in domain 28 is a column and might be a set of horizontally mutually offset samples in case of, and according to, the mutual temporal alignment, if applied. In case of FIG. 3, it has been assumed that no such temporal alignment took place so that both sets 42 and 24 are pure columns in the time/channel representation.

The actual coding is done in units of so-called temporal blocks 30. The term “temporal block” 30 is used so as to denote both a temporal portion of the multi-channel signal in domain 28, i.e., the set of coded channels, as well as a temporal portion of a certain coded channel. That is, for each temporal block 30, each coded channel has a temporal block such as block 140 depicted for some temporal block 30c and same are mutually co-located. The coding is done sequentially along these blocks 140, by following a coding/decoding order, which traverses the blocks 140 temporal block 30 by temporal block 30 with traversing temporally co-located blocks of the coded channels along a channel order corresponding to the order of the coded channels along axis 32. This coding/decoding order is illustrated in FIG. 3 at 60. That is, in case of temporal block 140 being the block currently to be coded/decoded, the previously decoded/encoded temporal blocks include all preceding temporal blocks of all coded channels as well as the temporally co-located temporal blocks of coded channels preceding the coded channel 92 of temporal block 140 in channel order. These previously coded/decoded temporal blocks and their samples are illustrated in FIG. 3 by way of shading. In this regard, note that in FIG. 3, merely one temporal block 140 has been illustrated explicitly in order to reduce the complexity of FIG. 3. Thus, in the specification herein, reference sign 140 is sometimes used to indicate the currently encoded/decoded temporal block or to stand representatively for all temporal blocks. Further, as depicted in FIG. 3, the partitioning of signal 14 into temporal blocks 30 and 140, respectively, might be done in a manner so that these blocks 30 and 140, respectively, are non-overlapping.

The actual coding in units of the temporal blocks 140 is performed predictively. That is, the encoder 10 comprises a block predictor 62 which predicts the samples of the currently coded temporal block 140, thereby yielding a prediction signal 64, and the prediction residual 66 formed by a subtraction between the actual sample values of temporal block 140 and the predicted samples of prediction signal 64 formed at a subtractor 68 is coded into the datastream 16 by residual coder 70. The residual coding in residual coder 70 may, or may not, involve a coding error by means of quantization. In any case, block predictor 62 uses the reconstructable version as being available by previously coded temporal blocks in order to obtain the prediction signal 64. This reconstructable version 72 might be derived at encoder 10 by means of a residual decoder 74 which reverses potential coding loss, such as quantization by means of dequantization, manifesting itself in the residual signal 76 coded into datastream 16, and an adder 78 which sums-up prediction signal 64 and the reconstructable residual signal 80 as obtained by residual decoder 74.

The decoder 12 decodes the coded channels from data stream 16 in a corresponding manner, i.e., in units of the temporal blocks 30 or in temporal blocks 140, respectively, and using predictive decoding. To this end, the decoder 12 comprises a residual decoder 82, an adder 84 and a block predictor 86 which correspond to, and are mutually connected in the same manner as, elements 74, 78 and 62 of encoder 10. That is, the residual decoder 82 derives from the residual signal 76 in data stream 16 the reconstructable residual signal 80 for a currently decoded temporal block 140 which is then subject to addition with prediction signal 64 derived by block predictor 86 for temporal block 140 on the basis of the reconstructed version 72 of previously decoded temporal blocks at adder 84. The output of adder 84, thus, yields the reconstructed version 72 of the currently decoded temporal block 140 and becomes part of the pool of already decoded samples of previously decoded temporal blocks when the temporal blocks of the coded channels are, in this manner, traversed along coding/decoding order 60 so as to reconstruct the coded channels in the coded domain 28.

In order to enable a high degree of random access capability, some of the temporal blocks 30 may be coded in a random access manner meaning that the coded channels therein are coded independent from previous temporal blocks 30. Imagine, for instance, that temporal blocks 30b and 30e are random access temporal blocks. Then, none of the temporal channel blocks 140 in temporal block 30b as well as 30e would depend on any preceding temporal block 140 such as none temporal block within temporal block 30a forming a coding dependency basis for any temporal channel block 140 in temporal block 30b and none of the temporal channel blocks 140 within temporal blocks 30a to 30d forming a coding dependency basis for any of the temporal channel blocks 140 within temporal block 30e. Thus, in other words, coding dependencies are restricted so as to not reach-out beyond the border of a random access temporal block 30b and 30e towards any preceding temporal block 30. Such restriction might also hold for intermediate temporal blocks 30c to 30d between random access temporal blocks 30b and 30e in that same may not depend on any temporal block preceding the leading one among the random access temporal blocks 30b and 30e, here block 30b. Accordingly, leading temporal borders of the random access temporal blocks 30b and 30e are indicated by bold lines in FIG. 3.

Further, it might be that the coding of the coded channels also interrupts or restricts inter-channel dependencies by coding one or more of the coded channels as random access coded channels so that coding dependencies of these random access coded channels, or even these random access coded channels and the intermediate coded channels therebetween, are restricted so as to not reach-out beyond such a random access coded channel toward any coded channel preceding that random access coded channel in channel order along axis 32. Two such random access coded channels 88a and 88b and their associated inter-channel dependency borders are illustrated in FIG. 3.

The block predictor 62 and 86 of encoder 10 and decoder 12, respectively, operate synchronously, i.e., they generate the same prediction signal 64 based on the previously encoded/decoded samples of previously encoded/decoded temporal blocks 140. On encoder side 10, the prediction for a certain temporal block 140 may be accompanied or determined by one or more prediction parameters. Same might be determined on encoder side based on a rate/distortion optimization. These prediction parameters 90 are coded into data stream 16 and they are decoded from data stream 16 and used by block predictor 86 so as to perform the same prediction.

It might be that encoder 10 and decoder 12 support more than one prediction mode. For instance, encoder 10 and decoder 12 may support an intra prediction mode (which mode may also be called block-copy mode) according to which the currently encoded/decoded temporal block 140 is predicted based on the reconstructable sample values of previously encoded/decoded temporal blocks of the same coded channel to which the currently encoded/decoded temporal block 140 belongs, which is coded channel 92 in the example of FIG. 3. Additionally or alternatively, encoder 10 and decoder 12 may support an inter-prediction mode (which mode may also be called cross-channel prediction mode) according to which the currently encoded/decoded temporal block 140 is predicted based on the reconstructable sample values of previously encoded/decoded temporal blocks of coded channels preceding—in coding order 32—the coded channel 92 to which the currently encoded/decoded temporal block 140 belongs. Additionally or alternatively, there may be a mixed prediction mode according to which the prediction signal 64 is obtained by both, reconstructed/reconstructable sample values of previously encoded/decoded temporal blocks of coded channel 92 itself as well as reconstructed/reconstructable sample values of coded channels preceding coded channel 92 in channel order along axis 32. Beyond this, there may be temporal blocks 140 which are coded without any prediction at encoder 10 and decoded without any prediction at decoder 12 such as the first temporal blocks in the tiles 94 resulting from mutually separating the temporal blocks by means of the random access borders 96 on the one hand and the random access channel borders 98 on the other hand. This corresponds to the prediction signal 64 being set to zero and this may form an additional mode which could be called bypass mode. Additionally, or alternatively, there may be other modes such as ones deriving a DC predictor or linear function predictor for block 64 based on immediately preceding samples of block 140. The prediction parameters 90 may, thus, contain for a currently encoded/decoded temporal block 140 a prediction mode flag or prediction mode indicator indicating the prediction mode to be used for this currently encoded/decoded temporal block 140 and, optionally, one or more parameters parameterizing the prediction mode to be used for this currently encoded/decoded temporal block 140.

The aforementioned coding dependencies ought not to cross any of the borders 96 and 98 not only result from the just-described sample prediction capabilities of block predictor 62 and 86, respectively, but may optionally also result from other mechanisms such as parameter prediction according to which parameters such as the aforementioned prediction parameters 90 for a certain temporal block 140 are predicted based on coding parameters conveyed in the data stream 16 for any previous temporal block, or context derivation for context-adaptive entropy coding/decoding any coding parameter such as the prediction parameters 90 or any other side information such as side information 76 and 36 for temporal block 140 based on any coding parameter conveyed in the data stream 16 for any preceding temporal block.

That is, summarizing, the encoder 10 encodes the multi-channel signal 14 by transferring it into the coded domain 28 and then coding the coded channels into data stream 16 in the just-described block-wise and predictive manner, wherein decoder 12 decodes the coded channels of coded domain 28 from data stream 16 and the corresponding block-wise and predictive manner with then gaining the multi-channel signal 14 in its original form 26 based on the coded channels in coded domain 28 by means of segment 38. As said, the channel transformation is optional and if not used, each sample 40 in the coded domain 28 really corresponds to one sample 18 in the original domain 26. If, further, the temporal mutual alignment is not used, each sample 40 exactly corresponds to a sample 18 in the original domain 26 at exactly the same time instant or, differently speaking, all temporally co-located samples 40 in coded domain 28 remain mutually temporally co-located in the original domain 26.

As mentioned before, FIG. 3 only represents a possible “framework” into which the previously described embodiments and the embodiments described subsequently may be built into. Many modifications may be performed with respect to FIG. 3, and some of these modifications might be mentioned in the subsequent description with respect to certain ones of the subsequently described embodiments, but these modifications shall then be treated as being also applicable with respect to other ones of the subsequently described embodiments. Further, as a final note, and without being treated as forming an exclusive list of further possible amendments of the description of FIG. 3, it shall be noted that the temporal blocks 30 might, other than illustrated in FIG. 3, vary in block length rather than being of a constant length as depicted in FIG. 3. For instance, encoder 10 may decide on the length of blocks 30 and signal the block length of blocks 30 (and the corresponding temporal blocks 140 of the coded channels) within data stream 16. Further, although not described before, it might be that residual coder and residual decoder 70 and 82 may use transform coding/decoding in order to convey the residual signal 76 in data stream 16. That is, the residual signal 80 may be conveyed in data stream 16 in transform domain by way of transform coefficients in residual signal 76. The transform domain might be a DCT, DST or an FFT. The transform may be non-overlapping, i.e. it may only transform residual signal 80 and its re-transform may only cover residual signal 76 within block 140, and/or may be non-windowed, i.e. the residual signal might be transformed without any transform window used to temporally shape the residual signal 80 before the transform. The transform domain, i.e. the transformation leading from time domain to transform domain which is used by the encoder to transform the prediction residual signal 80 to be coded und the corresponding re-transformation leading from transform domain to time domain which is used by the decoder to derive the prediction residual signal 80, or the transformation, might be selected from a set of available transforms including, for instance, one or more of 1) one or more DCTs, 2) one or more DSTs and 3) an identity transform according to which the prediction residual signal 80 is coded into the data stream 14 in time domain directly. Some deblocking processing might be used to avoid blocking artifacts. If, alternatively, an overlapped transform is used, an overlap-add processing with re-transforms of immediately preceding/succeeding temporal blocks of the same coded channel might be used in order to completely reconstruct the current temporal block's 140 residual signal 76. Besides such transform-(residual)-coded blocks there might be temporal blocks 140 which, additionally or alternatively, are coded using, besides the block prediction by block predictor 62/86—which could be called a primary prediction—a secondary sample-wise prediction of the residual samples in residual block 66 such as by predicting a current sample's residual sample by means of already decoded values of preceding—in sample coding order—residual samples in block 66 or 80, with then correcting same by means of a secondary-prediction-residual sample decoded from the data stream 16. The secondary-prediction-residual samples for such a block may coded into the data stream en block in a transform domain or sample-wise in time domain.

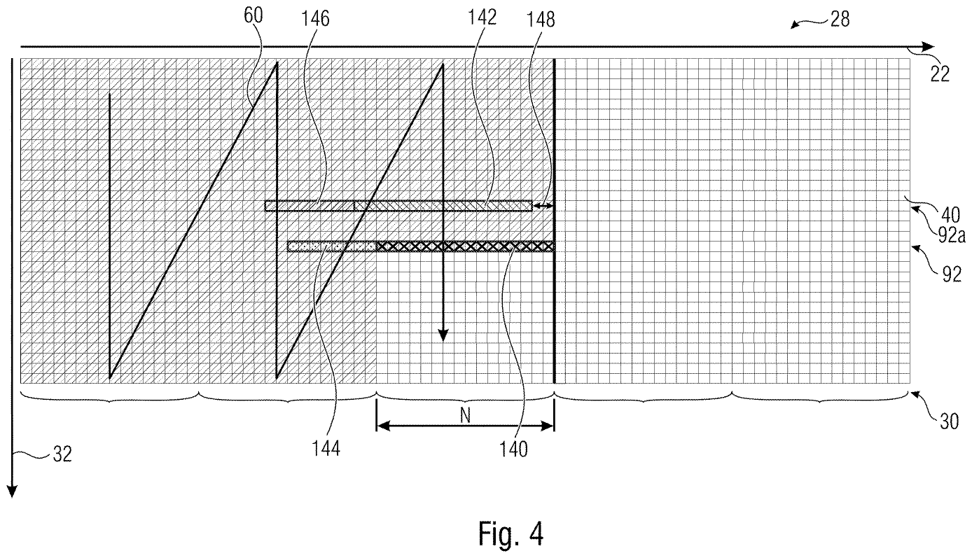

The description is now resumed with respect to the announced subsequently described embodiments, here namely embodiments relating to inter-channel prediction. As described with respect to FIG. 3, the embodiments with respect to decoder and encoder described in the following may relate to such decoders and encoders which comprise the inter-channel prediction as one mode among one or more others, but the inter-channel prediction mode may alternatively be the only available prediction mode. That is, generally, FIG. 4 relates to a decoder for decoding a multi-channel digital signal 14 from a data stream 16, which is configured to decode coded channels representing the multi-channel digital signal 14, namely those in domain 28, from the data stream 16 in temporal blocks 140, namely temporal coded channel blocks, with sequentially decoding from the data stream 16 a predetermined temporal block 140 of each of the coded channels before decoding a subsequent temporal block of any of the coded channels, and to an encoder for encoding a multi-channel digital signal 14 into a data stream 16, which is configured to encode coded channels representing the multi-channel digital signal 14, namely those in domain 28, into the data stream 16 in temporal blocks 140, namely temporal coded channel blocks, with sequentially decoding from the data stream 16 a predetermined temporal block 140 of each of the coded channels before decoding a subsequent temporal block of any of the coded channels.

In order to describe the inter-channel prediction mode, reference is made to FIG. 4. In encoding/decoding a currently encoded/decoded temporal block 140, one or more prediction parameters for predicting the current temporal block 140 are determined first. The one or more prediction parameters are for, or control, the prediction of the current temporal block 140 of a predetermined coded channel 92 based on a reference block portion 142 of a set of one or more reference channels 92a. In FIG. 4, merely one such reference channel 92a is illustrated to be used for the prediction of temporal block 140 for illustration purposes and ease of explanation, but the number may be larger than one. As became clear from the description above, reference channels such as reference channel 92a need to precede the predetermined coded channel 92 in channel coding order 32 and might have, for instance, a lower channel index associated therewith than compared to predetermined coded channel 92 comprising the currently encoded/decoded temporal block 140. A further note shall be made with respect to the term “reference block portion”. Reference block portions such as reference block portion 142 are portions of immediately consecutive samples 40 of the reference channel 92a, with a number of comprised immediately consecutive samples 40 being equal to the number of samples within temporal block 140, but they are not necessarily restricted to be registered or to be temporally located to temporal block 140 or to any other temporal block 30, i.e. they might be placed freely expect for the fact that reference block portions need to comprise or cover previously decoded/encoded samples only, and except for an optional maximum temporal distance to block 140. That is, the reference block portions such as reference block portion 142 might be temporally shifted relative to temporal block 140 as described in more detail below.

The one or more prediction parameters determined for temporal block 140 are for defining as to how, computationally, the prediction signal 64 for predicting temporal block 140 is derived from the reference block portion(s) 142 or to be more precise, the reconstructed/reconstructable samples in reference block portion(s) 142. As will be described in more detail below, the one or more prediction parameters may, for instance, define scale and offset such as a scale for each reference block portion 142 by means of which the reference block portion 142 is scaled (by multiplying it or, to be more precise, its reconstructed/reconstructable samples, by multiplication with the scale), with then adding the offset to the scaled reference block portion or, in case of more than one reference block portion 142, forming a sum over all scaled reference block portions and the offset.

The determination of the one or more prediction parameters is done based on temporal segments 144 and 146 of channels 92 and 92a, each consisting of immediately consecutive samples 40 of the respective channel, and each of which temporally preceding the corresponding block, i.e. block 140 in coded channel 92, and reference block portion 142 in channel 92a, respectively. For instance, segments 144 and 146 might be defined to be located immediately preceding the corresponding block 140 and 142, respectively, as illustrated in FIG. 4, but it might alternatively be that the temporal positioning of segments 144 and 146 is defined in a different manner such as in a manner so that the segments 144 and 146 are mutually temporally co-located such that, for instance, all segments 144 and 146 contain the samples 40 immediately preceding, temporally, the block among block 140 and block 142 which is the earliest in time. As can be seen in FIG. 4, segments 144 and 146 mutually coincide in the number of samples 40 contained therein, wherein this number L may be equal to or different from the number N of samples in blocks 140 and 142, respectively. For instance, L might be chosen to be smaller than N as illustrated in FIG. 4.

The advantage of determining the one or more prediction parameters using which temporal block 140 is predicted from the reference block portion 142 of the one or more reference channels 92a based on an evaluation of the temporal segments 144 and 146, is the fact that this determination may be done by both encoder 10 and decoder 12 because the temporal segments 144 and 146 are both comprised by the reservoir or pool of already encoded/decoded samples so that the determination of the one or more prediction parameters may be done inherently without any explicit signaling in data stream 16, thereby reducing the side information signaling overhead.

The determination itself is done in the following manner: in particular, it is a pretty good assumption that a relationship of the currently encoded/decoded temporal block 140 to the reference block portion 142 of the one or more reference channels 92a is the same as, or is at least pretty close to, the relationship of temporal segment 144 of coded channel 92 relative to the temporal reference segment 146 in each reference channel 92a. Thus, if the one or more prediction parameters are determined so that their application onto the temporal reference segment 146 of the one or more reference channels 92a results into a “prediction” for temporal segment 144 which minimizes the prediction residual towards the temporal segment 144, this one or more prediction parameter should, if the assumption holds true, also minimize the deviation of the prediction signal 64 obtained by applying the one or more prediction parameters thus determined onto the reference block portion 142 of the one or more reference channels 92a from the block 140 to be coded/decoded. As a result, the prediction residual 80 coded into data stream 16 may be coded with fewer bits due to the preciseness in having derived prediction signal 64.

If the one or more prediction parameters consist of a scale for the, in case of only one reference block portion, reference block portion 142 or for each reference block portion 142 in case of having more than one reference block portion, and an offset, as just-described, then the determination of this scale and offset may be performed as follows with here assuming that x₁, . . . , x_{N} denote the reconstructed/reconstructable samples in segment 144, while y_{i,j} denotes the j^{th} sample in segment 146 of the i^{th} reference block portion with iϵ{1, . . . , K}, and jϵ{1, . . . , L} and λᵢ denoting the scale for the i^{th} reference block portion and b denoting the offset. Then, the minimization of the deviation when applying the prediction parameters onto y_{i,j} from samples xⱼ in terms of sum of squares, i.e.

$${\sum }_{j = 1}^{L} {( {x}_{j} - {\sum }_{i = 1}^{K} ( {λ}_{i} \cdot {y}_{i , j} - b ) )}^{2} \to min$$

is achieved by the solution of the following equation and, thus, decoder and encoder solve this linear equation and in doing so, decoder and encoder may use a lookup table in order to avoid the computation of the scale and offset involving a division. The equation is:

$$M \cdot ( \begin{matrix}\begin{matrix}\begin{matrix}{λ}_{1} \\ ⋮\end{matrix} \\ {λ}_{K}\end{matrix} \\ 1\end{matrix} ) = ω with$$

$$M = {( {M}_{k , l} )}_{k , l = 1}^{K + 1} ∈ {ℝ}^{( K + 1 ) \times ( K + 1 )}$$

$${M}_{k , l} = \{ \begin{matrix}{\sum }_{j = 1}^{L} ( {y}_{k , j} \cdot {y}_{l , j} ) , if k , l \leq K \\ {\sum }_{j = 1}^{L} {y}_{k , j} , if l = K + 1 and k \leq K \\ {\sum }_{j = 1}^{L} {y}_{l , j} , if k = K + 1 and l \leq K \\ L , if k = l = K + 1\end{matrix}$$

$$ω = ( {ω}_{1} , … , {ω}_{K + 1} ) ∈ {ℝ}^{K + 1}$$

$${ω}_{i} = \{ \begin{matrix}{\sum }_{j = 1}^{L} {x}_{j} \cdot {y}_{i , j} , if i \leq K \\ {\sum }_{j = 1}^{L} {x}_{j} , if i = K + 1\end{matrix}$$

Thus, as described, the inter-prediction according to FIG. 4 may involve one or more reference block portions 142 and the computation of the one or more prediction parameters may be performed in a manner avoiding a division which is approximated by way of a table lookup instead.

It is further noted that, in case of more than one reference block portion 142 being used for the currently encoded/decoded temporal block 140, each one of same is, according to an embodiment, contained in a separate one of the reference channels. That is, each reference channel would have exactly one reference block portion. However, as an alternative, it might be that the reference block portions partially, or all of same, belong to a common reference channel such as reference channel 92a.

As already mentioned above, the reference block portion(s) 142 might be located temporally offset relative to temporal block 140. For instance, datastream 16 may have, for each of a set of one or more inter-channel predicted channels out of the coded channels, for each of the one or more reference channels, a temporal offset 148 encoded thereinto at which 1) the reference block portion 142 of the respective reference channel 92a is temporally offset, such as delayed as depicted in FIG. 4, relative to the current temporal block 140 of the predetermined coded channel, and 2) the preceding temporal reference block portion 146 of the respective reference channel 92a is temporally offset, such as delayed as depicted in FIG. 4, relative to the preceding temporal block portion 144 of the predetermined coded channel 92. The decoder 12 decodes the temporal offset 48 from the datastream 16 accordingly. The granularity at which this temporal offset 48 is coded in the data stream 16 may be designed in one of the following options: for instance, the temporal offset 48 for each reference channel for a certain inter-channel predicted coded channel might be coded into datastream 16 at a scope valid for the whole datastream, or may be coded for each sequence of temporal blocks 30 from a random access temporal block such as 30b until the temporal block 30d immediately preceding the next random access temporal block 30e, or may be conveyed in datastream 16 temporal block individually, i.e. for each inter-predicted temporal block such as segment 140, individually. The set of one or more inter-channel predicted coded channels may include all channels except for the random access coded channels 88a and 88b (wherein in FIG. 3 the coded channel corresponding to the uppermost sample line might also be a random access coded channel, as it might be the first channel in channel order 32). The number of reference channels might also be coded in the datastream 16 in any of the just-mentioned granularities and even at a granularity which differs from the granularity at which the temporal offset signaling is done. The number of reference channels might be chosen to be equal for all inter-channel predicted coded channels, or might be signaled in the datastream 16 in a manner so that the number of reference channels differs among the inter-channel predicted channels. In case of allowing two reference block portions to belong to the same reference channel, for each reference channel, it might additionally be signaled as to how many reference block portions are contained in the respective reference channel for a certain inter-channel predicted coded channel. In any case, the decoder uses the temporal offset 48 coded in the datastream in order to cut-out out of the respective reference channel, or derive, the reference block portion 142 and the preceding temporal reference block portion 146 from the respective reference channel 92a using the temporal offset 148 signaled for the respective reference channel. Further, the datastream 16 may have, for each of the set of one or more reference channels, a channel index coded thereinto, which identifies the respective reference channels out of the coded channels which precede the coded channel 92 in channel order 32. Alternatively, the set of one more reference channels of a certain inter-channel predicted coded channel might, by default, include all those coded channels preceding in channel order 32, which immediately precede the current channels 92 in channel order. As described before, for each inter-channel predicted coded channel, the number of coded channels which may form one of the set of one or more reference channels, is restricted as same are merely allowed to be recruited from the coded channels preceding the respective inter-channel predicted coded channel up to the nearest preceding random access channel such as channel 88a in case of channel 92 in FIG. 3. Accordingly, a channel index conveyed in the datastream 16 may be coded into datastream 16, and may be decoded therefrom, using a parametrized binarization, such as a truncated unary code, parametrized using a binarization parameter, such as the truncation parameter, which might be set by encoder and decoder in such a manner so that the number of binary strings formed by the parametrized binarization becomes closest to—with becoming equal or greater than—this number of coded channels preceding the respective inter-channel predicted coded channel in channel order 32 up to the nearest—in channel order—preceding random access channel. With respect to the temporal offset 148 and the derivation of the temporal reference block portion 46 and the reference block portion 142 from the reference channel 92a, the following is noted. In particular, according to an embodiment, the temporal offset 148 is restricted to full-sample offsets, meaning that the temporal reference block portion 146 as well as the reference block portion are respectively formed by consecutive samples 40 of the corresponding reference channel, the consecutive samples being shifted relative to the samples of block portion 144 and segment 140, respectively, by a number of samples indicated by offset 148. The derivation of reference block portion 146 and reference block portion 142 is, thus, merely a cutting-out of the corresponding samples out of the samples of reference channel 92a. However, alternatively, the temporal offset 148 may also allow for sub-sample offsets so that the derivation might include a sub-sampling of the reference channel to result into reference block portion 146 and reference block portion 142, respectively.

A further note shall be made with respect to the freedom for encoder 10 to choose the temporal offset 148, the number of reference channels and the selection of the number of reference channels out of the available preceding coded channels for a certain coded channel 92, or for a subset of these settings. For instance, the encoder 10 may determine these parameters or settings as optimization variables in a rate/distortion optimization scheme, or may select same in a different manner such as by inspecting certain similarity measures or the like.

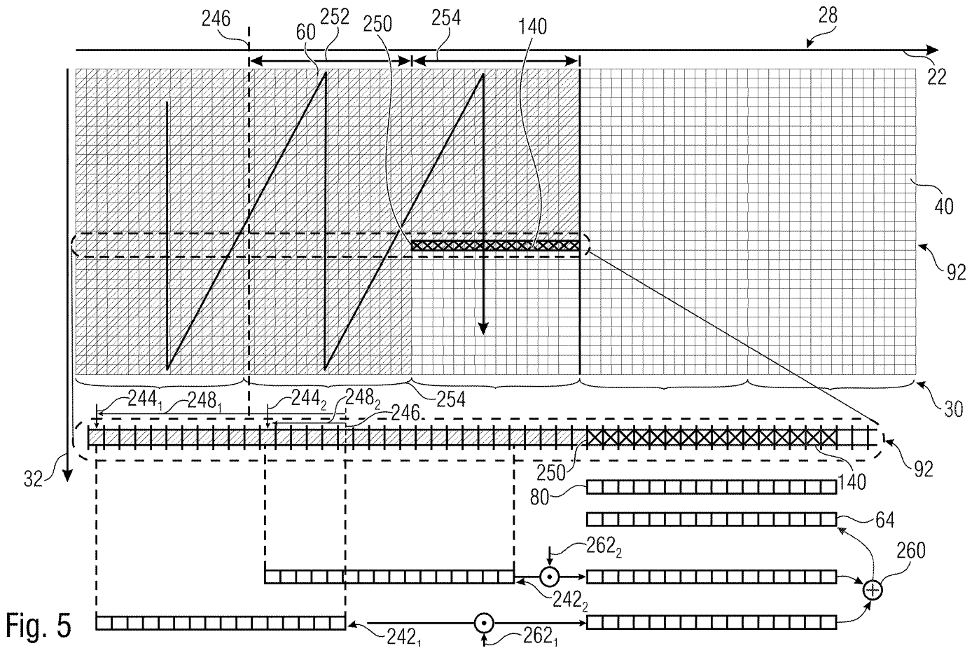

In the following, the announced subsequent embodiments dealing with intra prediction are presented. As outlined above, these details describe an encoder and a decoder for encoding/decoding a multi-channel digital signal 14, wherein these embodiments may be combined with a teaching of a possible framework presented above with respect to FIG. 3, both with adopting all details presented with respect to FIG. 3 as well as combining subsequent embodiments merely with a subset of these details. Generally, FIG. 5 presents embodiments for a decoder configured to decode coded channels representing a multi-channel digital signal 14 from the data stream 16 in temporal blocks 140, and an encoder configured to encoder coded channels representing a multi-channel digital signal 14 into the data stream 16 in temporal blocks 140.

According to FIG. 4, 5 current temporal block 140 of a predetermined coded channel is predicted from one or more reference block portions 242₁ and 242₂ of the same channel, i.e. the predetermined coded channel 92. The “reference block portions” equal the currently encoded/decoded temporal block 140 in the number of samples, but same are not restricted to be registered to any of the temporal blocks 30 and beyond this, in accordance with the embodiments described herein below, they might be positioned at, and be derived from, sub-sample positions of channel 92.

In FIG. 5, the number of reference block portions is two but this number may also be one or be larger than two. In particular, the number of reference block portions might be determined by the encoder 10 and signaled in the datastream. The number might be determined for each intra-predicted temporal block 140 individually and signaled in the datastream for that segment 140 individually. Alternatively, the number is signaled in the datastream 16 at a coarser time/channel grid. For instance, the number might be signaled in the datastream channel-globally, i.e. for all coded channels, with being updated intermittently such as for each temporal block 30 or for each sequence of temporal blocks 30 from a random access temporal block such as segment 30b up to the temporal block 30d immediately preceding the next random access temporal block 30e. Even alternatively, the number of reference block portions might be signaled in the datastream 16 channel-individually but for a period comprising more than just one temporal block 140 of that channel such as channel 92.

The datastream 16 might have, for each of the one or more reference block portions 242₁ and 242₂, a position 244₁, 244₂ of the respective reference block portion coded thereinto. In particular, this position might be the starting position of the respective reference block portion as depicted in FIG. 5. As the starting position needs to be distanced from the beginning 250 of the intra-predicted temporal block 140 by at least a temporal distance 252 equaling the temporal length 254 of temporal block 140 itself, the starting position 244_{1/2} might be coded into the datastream as a temporal offset 2481 and 2482 relative to a temporal reference position 246 lying at the temporal distance 252 ahead beginning 250.

The position may be coded into the datastream 16 at sample accuracy or at sub-sample accuracy. According to an embodiment, it is signaled in the datastream whether the position is coded into the datastream at sample accuracy or sub-sample accuracy and, in case of more than one sub-sample accuracy being available, at which sub-sample accuracy. The signaling of this accuracy may, again, be done individually for the intra-predicted temporal block 140, or be done at a coarser temporal and/or channel grid. For instance, the accuracy may be signaled channel-globally, i.e. for all coded channels commonly, and in temporal terms, it may be signaled in the datastream for the whole datastream or for each sequence of temporal blocks 30 from a random access temporal block onwards up to the temporal block immediately preceding the next random access temporal block, or for each temporal block 30. Even alternatively, the accuracy may be signaled channel-individually but for periods encompassing more than just one temporal block 140.

If the position of a predetermined reference block portion 242_{1/2} falls onto a sub-sample position, the predetermined reference block portion 242_{1/2} is derived from channel 92 by sampling this channel 92 using an interpolation filter at a grid of sub-sample positions which grid has a temporal length of temporal block 142, i.e. has the same number of samples, and is placed at the sub-sample position 244_{1/2}.

If the number of reference block portions 142_{1/2} is larger than one, as it is the case in FIG. 5, the prediction signal 64 of temporal block 140 may be derived based on a sum 260 of the reference block portions 242₁ and 242₂. The sum may be a weighted sum so that reference block portion 242₁ is weighted using a factor 262₁ before being subject to addition 260, while reference block portion 242₂ might be weighted by a factor 2622 before being subject to addition 260. Again, the same statements on granularity of signalization as done above with respect to the position signaling holds true with respect to a signalization of one, a subset of, or all of the weights/factors 262_{1/2} in datastream 16, wherein the granularity may be equal to the one of the signalization of the position or different thereto. However, the weights might be set be default and, optionally, they might be equal to each other, such as the inverse of the number of reference block partitions.

Further, adaptive filtering with signaled filter coefficients might be used to filter either the weighted sum of individual weighted reference block portions, or one or more of the reference block portions before being used to from the prediction signal in combination with the other reference block portion(s).

Generally, and using a pseudo-code like writing, the following options for transmitting the reference block portions' offsets and the filter decision shall explicitly be mentioned (with steps in parenthesis being optional):
A) (decode/encode number of reference block portions) (NOTE: for this temporal block individually or at a larger temporal scope)
For each reference block portion
   decode/encode offset unit indicator (NOTE: one of full-sample, half-sample units or the like)
   decode/encode number of offset units (NOTE: so that offset is this number times offset unit)
if there is no reference block portion with sub-sample offset, (NOTE: that is, no reference block portion which requires interpolation filter)
decode/encode filter flag
if there is a reference block portion with sub-sample offset,
infer that the filter flag indicates no filtering
if filter flag indicates filtering,
decode/encode filter information (NOTE: this filter might be applied to weighted sum to yield final prediction signal 64)
B)
(decode/encode number of reference block portions) (NOTE: for this temporal block individually or at a larger temporal scope)
decode/encode offset unit indicator (NOTE: one of full-sample, half-sample units or the like)
For each reference block portion
   decode/encode number of offset units (NOTE: so that offset is this number times offset unit)
if there is no reference block portion with sub-sample offset, (NOTE: that is, no reference block portion which requires interpolation filter)
decode/encode filter flag (NOTE: otherwise it may deemed to be none-indicative of filtering)
if filter flag indicates filtering,
decode/encode filter information (NOTE: this filter might be applied to weighted sum to yield final prediction signal 64)
C)
(decode/encode number of reference block portions) (NOTE: for this temporal block individually or at a larger temporal scope)
decode/encode filter flag
if filter flag indicates filtering,
decode/encode filter information (NOTE: this filter might be applied to weighted sum to yield final prediction signal 64)
   infer that offset unit indicator of each temporal block portion indicates full-sample offset unit
if filter flag not indicates filtering,
For each reference block portion
if filter flag not indicates filtering,
   decode/encode offset unit indicator (NOTE: one of full-sample, half-sample units or the like)
   decode/encode number of offset units (NOTE: so that offset is this number times offset unit)
D)
(decode/encode number of reference block portions) (NOTE: for this temporal block individually or at a larger temporal scope)
For each reference block portion
decode/encode offset unit indicator (NOTE: one of full-sample, half-sample units or the like)
decode/encode number of offset units (NOTE: so that offset is this number times offset unit)
if respective block portion has no sub-sample offset, (NOTE: that is, this reference block portion does not require interpolation filter)
decode/encode filter flag
if filter flag indicates filtering,
decode/encode filter information (NOTE: otherwise no filtering (except interpolation filtering) takes place)
E)
(decode/encode number of reference block portions) (NOTE: for this temporal block individually or at a larger temporal scope)
For each reference block portion
   decode/encode offset unit indicator (NOTE: one of full-sample, half-sample units or the like)
   decode/encode number of offset units (NOTE: so that offset is this number times offset unit)
decode/encode filter flag
if filter flag indicates filtering,
decode/encode filter information (NOTE: this filter might be applied to weighted sum to yield final prediction signal 64)
F)
(decode/encode number of reference block portions) (NOTE: for this temporal block individually or at a larger temporal scope)
decode/encode offset unit indicator (NOTE: one of full-sample, half-sample units or the like)
For each reference block portion
   decode/encode number of offset units (NOTE: so that offset is this number times offset unit)
decode/encode filter flag
if filter flag indicates filtering,
decode/encode filter information (NOTE: this filter might be applied to weighted sum to yield final prediction signal 64)
G)
(decode/encode number of reference block portions) (NOTE: for this temporal block individually or at a larger temporal scope)
For each reference block portion
decode/encode offset unit indicator (NOTE: one of full-sample, half-sample units or the like)
decode/encode number of offset units (NOTE: so that offset is this number times offset unit)
decode/encode filter flag
if filter flag indicates filtering,
decode/encode filter information (NOTE: otherwise no filtering (except, potentially, interpolation filtering) takes place)

As described in FIG. 3, the datastream 16 has a prediction residual 80 encoded thereinto which forms the prediction residual of prediction signal 64 and might be used to correct prediction signal 64, such as by addition, to yield the reconstruction of temporal block 140.

### Implementation Alternatives:

Although some aspects have been described in the context of an apparatus, it is clear that these aspects also represent a description of the corresponding method, where a block or device corresponds to a method step or a feature of a method step. Analogously, aspects described in the context of a method step also represent a description of a corresponding block or item or feature of a corresponding apparatus. Some or all of the method steps may be executed by (or using) a hardware apparatus, like for example, a microprocessor, a programmable computer or an electronic circuit. In some embodiments, one or more of the most important method steps may be executed by such an apparatus.

Depending on certain implementation requirements, embodiments of the invention can be implemented in hardware or in software. The implementation can be performed using a digital storage medium, for example a floppy disk, a DVD, a Blu-Ray, a CD, a ROM, a PROM, an EPROM, an EEPROM or a FLASH memory, having electronically readable control signals stored thereon, which cooperate (or are capable of cooperating) with a programmable computer system such that the respective method is performed. Therefore, the digital storage medium may be computer readable.

Some embodiments according to the invention comprise a data carrier having electronically readable control signals, which are capable of cooperating with a programmable computer system, such that one of the methods described herein is performed.

Generally, embodiments of the present invention can be implemented as a computer program product with a program code, the program code being operative for performing one of the methods when the computer program product runs on a computer. The program code may for example be stored on a machine readable carrier.

Other embodiments comprise the computer program for performing one of the methods described herein, stored on a machine readable carrier.

In other words, an embodiment of the inventive method is, therefore, a computer program having a program code for performing one of the methods described herein, when the computer program runs on a computer.

A further embodiment of the inventive methods is, therefore, a data carrier (or a digital storage medium, or a computer-readable medium) comprising, recorded thereon, the computer program for performing one of the methods described herein. The data carrier, the digital storage medium or the recorded medium are typically tangible and/or non-transitionary.

A further embodiment of the inventive method is, therefore, a data stream or a sequence of signals representing the computer program for performing one of the methods described herein. The data stream or the sequence of signals may for example be configured to be transferred via a data communication connection, for example via the Internet.

A further embodiment comprises a processing means, for example a computer, or a programmable logic device, configured to or adapted to perform one of the methods described herein.

A further embodiment comprises a computer having installed thereon the computer program for performing one of the methods described herein.

A further embodiment according to the invention comprises an apparatus or a system configured to transfer (for example, electronically or optically) a computer program for performing one of the methods described herein to a receiver. The receiver may, for example, be a computer, a mobile device, a memory device or the like. The apparatus or system may, for example, comprise a file server for transferring the computer program to the receiver.

In some embodiments, a programmable logic device (for example a field programmable gate array) may be used to perform some or all of the functionalities of the methods described herein. In some embodiments, a field programmable gate array may cooperate with a microprocessor in order to perform one of the methods described herein. Generally, the methods are advantageously performed by any hardware apparatus.

The apparatus described herein may be implemented using a hardware apparatus, or using a computer, or using a combination of a hardware apparatus and a computer.

The apparatus described herein, or any components of the apparatus described herein, may be implemented at least partially in hardware and/or in software.

The methods described herein may be performed using a hardware apparatus, or using a computer, or using a combination of a hardware apparatus and a computer.

The methods described herein, or any components of the apparatus described herein, may be performed at least partially by hardware and/or by software.

While this invention has been described in terms of several embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations and equivalents as fall within the true spirit and scope of the present invention.

1. Decoder for decoding a digital time-varying signal from a data stream, configured to
decode the digital time-varying signal from the data stream in temporal blocks by decoding each temporally residual-predicted temporal block of the digital time-varying signal by
predicting the respective temporally residual-predicted temporal block using a selected prediction mode out of a set of prediction modes to acquire a prediction signal,
determining a prediction residual signal of the respective temporally residual-predicted temporal block, and
correcting the prediction signal using the prediction residual signal,
wherein, in the determining the prediction residual signal, sequentially decode second-stage-predicted residual samples of residual samples of the respective temporally residual-predicted temporal block along a sample order by
deriving a second-stage residual sample prediction value for a currently decoded second-stage-predicted residual sample based on already decoded residual samples within a template of a predetermined number of sample positions preceding the currently decoded second-stage-predicted residual sample in sample order,
decoding a second-stage-correction value for the currently decoded second-stage-predicted residual sample from the data stream, and
correcting the second-stage residual sample prediction value using the second-stage-correction value.

2. Decoder of claim 1, configured to, in the deriving the second-stage residual sample prediction value, perform a linear prediction based on the already decoded residual samples within the template.

3. Decoder of claim 1, configured to, in the deriving the second-stage residual sample prediction value, form a weighted sum of the already decoded residual samples within the template.

4. Decoder of claim 1, configured to, in the decoding the second-stage-correction value for the currently decoded second-stage-predicted residual sample from the data stream, use entropy decoding.

5. Decoder of claim 1, configured to decode each of transform coded temporal blocks of the temporally residual-predicted temporal blocks by deriving the second-stage-correction value of the second-stage-predicted residual samples by means of a re-transformation applied to the transform coefficients signaled in the data stream for the respective transform coded temporal block.

6. Decoder of claim 5, configured to decode the transform coefficients for the respective transform coded temporal block from the data stream by decoding an end-sample position from the data stream and inferring that all transform coefficients of the respective transform coded temporal block following the end-sample-position along a transform coefficient coding order are zero.

7. Decoder of claim 1, wherein the set of prediction modes comprises a bypass prediction mode according to which the prediction signal of the respective temporally residual-predicted temporal block is set to zero, wherein the decoder is configured to,
in the determining the prediction residual signal,
check whether the selected prediction mode of the respective temporally residual-predicted temporal block is the bypass prediction mode,
if the selected prediction mode of the respective temporally residual-predicted temporal block is the bypass prediction mode, sequentially decode, along the sample order, each of first residual samples of the residual samples of the respective temporally residual-predicted temporal block, which, along the sample order, are closer to a block border of the respective temporally residual-predicted temporal block than the predetermined number, by using the template of the predetermined number of sample positions preceding a respective first residual sample with
deriving a residual sample prediction value for the respective first residual sample based on, for each sample position of the template, which lies beyond the block border, an already decoded sample of the digital time-varying signal which is comprised by a temporal block preceding the respective temporally residual-predicted temporal block and is positioned at the respective sample position, and, for each sample position of the template, which lies within the respective temporally residual-predicted temporal block, an already decoded residual sample which is comprised by the respective temporally residual-predicted temporal block and is positioned at the respective sample position,
decoding a correction value for the respective first residual sample from the data stream, and
correcting the residual sample prediction value using the correction value.

8. Decoder of claim 7, wherein, for each sample position of the template, which lies beyond the block border, the respective already decoded sample of the digital time-varying signal corresponds to a prediction sample of the prediction signal at the respective sample position within the temporal block preceding the respective temporally residual-predicted temporal block corrected using a prediction residual sample of the prediction residual signal at the respective sample position within the temporal block preceding the respective temporally residual-predicted temporal block.

9. Decoder of claim 7, configured to, in the deriving the residual sample prediction value, perform a linear prediction based on already known sample values, one for each sample position of the template and formed by an already decoded sample of the digital time-varying signal which is comprised by a temporal block preceding the respective temporally residual-predicted temporal block or an already decoded residual sample of the respective temporally residual-predicted temporal block at the respective sample position.

10. Decoder of claim 7, configured to, in the deriving the residual sample prediction value, form a weighted sum of addends, one for each sample position of the template and formed by an already decoded sample of the digital time-varying signal which is comprised by a temporal block preceding the respective temporally residual-predicted temporal block or an already decoded residual sample of the respective temporally residual-predicted temporal block at the respective sample position.

11. Decoder of claim 10, configured to,
in the deriving the second-stage residual sample prediction value, form a weighted sum of the already decoded residual samples within the template, and
configured to use, in the deriving the second-stage residual sample prediction value and the deriving the residual sample prediction value, for each sample position, a weight which is commonly used for the deriving the second-stage residual sample prediction value and the deriving the residual sample prediction value, respectively.

12. Decoder of claim 7, configured to perform the decoding the correction value for the currently decoded first residual sample from the data stream using entropy decoding.

13. Decoder of claim 7, configured to decode each of transform coded temporal blocks of the temporally residual-predicted temporal blocks by deriving the correction value of the first residual samples by means of a re-transformation applied to the transform coefficients signaled in the data stream for the respective transform coded temporal block.

14. Decoder of claim 13, configured to decode the transform coefficients for the respective transform coded temporal block from the data stream by decoding an end-sample position from the data stream and inferring that all transform coefficients of the respective transform coded temporal block following the end-sample-position along a transform coefficient coding order are zero.

15. Decoder of claim 7, wherein the digital time-varying signal is a predetermined coded channel of coded channels representing a multi-channel digital signal.

16. Decoder of claim 15, configured to,
if the selected prediction mode of the respective temporally residual-predicted temporal block is the bypass prediction mode, sequentially decode, along the sample order, each of the first residual samples of the residual samples of the respective temporally residual-predicted temporal block, with
deriving a further residual sample prediction value for the respective first residual sample based on a set of consecutive already decoded samples of a further digital time-varying signal which is a further predetermined coded channel of the coded channels, and
correcting both the residual sample prediction value and the further residual sample prediction value using the correction value.

17. Decoder of claim 1,
wherein the set of prediction modes comprises a bypass prediction mode according to which the prediction signal of the respective temporally residual-predicted temporal block is set to zero, wherein the decoder is configured to, in the determining the prediction residual signal,
check whether the selected prediction mode of the respective temporally residual-predicted temporal block is the bypass prediction mode,
if the selected prediction mode of the respective temporally residual-predicted temporal block is not the bypass prediction mode,
for each of a number of consecutive block sample positions within a temporal block preceding the respective temporally residual-predicted temporal block from a block border of the respective temporally residual-predicted temporal block, the number of consecutive block sample positions equaling the predetermined number of sample positions,
extend the prediction of the respective temporally residual-predicted temporal block using the selected prediction mode onto the respective block sample position to acquire an extended prediction sample value for the respective sample position,
derive an artificial prediction residual sample value for the respective block sample position based on the extended prediction sample value for the respective block sample position and an already decoded sample of the digital time-varying signal within a temporal block preceding the respective temporally residual-predicted temporal block at the respective block sample position, and
sequentially decode, along the sample order, each of first residual samples of the residual samples of the respective temporally residual-predicted temporal block, which, along the sample order, are closer to a block border of the respective temporally residual-predicted temporal block than the predetermined number, by
deriving a residual sample prediction value for the respective first residual sample based on, for each sample position of the template, which lies beyond the block border, the artificial prediction residual sample value at the respective sample position and, for each sample position of the template, which lies within the respective temporally residual-predicted temporal block, an already decoded residual sample which is comprised by the respective temporally residual-predicted temporal block and is positioned at the respective sample position,
decoding a correction value for the respective first residual sample from the data stream, and
correcting the residual sample prediction value using the correction value.

18. Decoder of claim 1, configured to, in the determining the prediction residual signal,
for each of a number of consecutive block sample positions within a temporal block preceding the respective temporally residual-predicted temporal block from a block border of the respective temporally residual-predicted temporal block, the number of consecutive block sample positions equaling the predetermined number of sample positions,
extend the prediction of the respective temporally residual-predicted temporal block using the selected prediction mode onto the respective block sample position to acquire an extended prediction sample value for the respective sample position,
derive an artificial prediction residual sample value for the respective block sample position based on the extended prediction sample value for the respective block sample position and an already decoded sample of the digital time-varying signal within a temporal block preceding the respective temporally residual-predicted temporal block at the respective block sample position, and
sequentially decode, along the sample order, each of first residual samples of the residual samples of the respective temporally residual-predicted temporal block, which, along the sample order, are closer to a block border of the respective temporally residual-predicted temporal block than the predetermined number, by
deriving a residual sample prediction value for the respective first residual sample based on, for each sample position of the template, which lies beyond the block border, the artificial prediction residual sample value at the respective sample position and, for each sample position of the template, which lies within the respective temporally residual-predicted temporal block, an already decoded residual sample which is comprised by the respective temporally residual-predicted temporal block and is positioned at the respective sample position,
decoding a correction value for the respective first residual sample from the data stream, and
correcting the residual sample prediction value using the correction value.

19. Decoder of claim 17, configured to, in the derive the artificial prediction residual sample value for the respective block sample position, subtract the extended prediction sample value for the respective block sample position from the already decoded sample of the digital time-varying signal within the temporal block preceding the respective temporally residual-predicted temporal block at the respective block sample position.

20. Decoder of claim 17, wherein, for each of the number of consecutive block sample positions within the temporal block preceding the respective temporally residual-predicted temporal block from the block border of the respective temporally residual-predicted temporal block, the already decoded sample of the digital time-varying signal within a temporal block preceding the respective temporally residual-predicted temporal block at the respective block sample position corresponds to a prediction sample of the prediction signal at the respective sample position within the temporal block preceding the respective temporally residual-predicted temporal block corrected using a prediction residual sample of the prediction residual signal at the respective sample position within the temporal block preceding the respective temporally residual-predicted temporal block.

21. Decoder of claim 17, configured to, in the deriving the residual sample prediction value, perform a linear prediction based on, for each sample position of the template, which lies beyond the block border, the artificial prediction residual sample value at the respective sample position and, for each sample position of the template, which lies within the respective temporally residual-predicted temporal block, an already decoded residual sample which is comprised by the respective temporally residual-predicted temporal block and is positioned at the respective sample position.

22. Decoder of claim 17, configured to, in the deriving the residual sample prediction value, form a weighted sum of addends, one for each sample position of the template and formed by the artificial prediction residual sample value which is comprised by a temporal block preceding the respective temporally residual-predicted temporal block or the already decoded residual sample of the respective temporally residual-predicted temporal block at the respective sample position.

23. Decoder of claim 22, configured to,
in the deriving the second-stage residual sample prediction value, form a weighted sum of the already decoded residual samples within the template, and
configured to use, in the deriving the second-stage residual sample prediction value and the deriving the residual sample prediction value, for each sample position, a weight which is commonly used for the deriving the second-stage residual sample prediction value and the deriving the residual sample prediction value, respectively.

24. Decoder of claim 17, configured to, in the decoding the correction value for the respective first residual sample from the data stream, use entropy decoding.

25. Decoder of claim 17, configured to decode each of transform coded temporal blocks of the temporally residual-predicted temporal blocks by deriving the correction value of the first residual samples by means of a re-transformation applied to the transform coefficients signaled in the data stream for the respective transform coded temporal block.

26. Decoder of claim 25, configured to decode the transform coefficients for the respective transform coded temporal block from the data stream by decoding an end-sample position from the data stream and inferring that all transform coefficients of the respective transform coded temporal block following the end-sample-position along a transform coefficient coding order are zero.

27. Decoder of claim 1, wherein the set of prediction modes comprises a bypass prediction mode according to which the prediction signal of the respective temporally residual-predicted temporal block is set to zero, wherein the decoder is configured to, in the determining the prediction residual signal,
check whether the selected prediction mode of the respective temporally residual-predicted temporal block is the bypass prediction mode,
if the selected prediction mode of the respective temporally residual-predicted temporal block is not the bypass prediction mode, decode first residual samples of the residual samples of the respective temporally residual-predicted temporal block, which, along the sample order, are closer to a block border of the respective temporally residual-predicted temporal block than the predetermined number, without using the template.

28. Decoder of claim 1, wherein the decoder is configured to, in the determining the prediction residual signal, decode first residual samples of the residual samples of the respective temporally residual-predicted temporal block, which, along the sample order, are closer to a block border of the respective temporally residual-predicted temporal block than the predetermined number, without using the template.

29. Decoder of claim 27, configured to, in the decode the first residual samples of the residual samples of the respective temporally residual-predicted temporal block from the data stream, use entropy decoding.

30. Decoder of claim 29, configured to,
in the decoding the second-stage-correction value for the currently decoded second-stage-predicted residual sample from the data stream, use entropy decoding,
wherein the decoder is configured to use a first set of one or more context models in the decode the first residual samples and a second set of one or more context models in the decoding the second-stage-correction value.

31. Decoder of claim 30, wherein the first set of one or more context models is different from the second set of one or more context models.

32. Decoder of claim 30, configured to decode the first residual samples and the second-stage-correction value for the currently decoded second-stage-predicted residual sample using a binarization which comprises a significance bin and one or more greater-x-flags, and to use the first and second set of one or more context models to entropy code the significance bin and the one or more greater-x-flags.

33. Decoder of claim 30, configured to decode each of transform coded temporal blocks of the temporally residual-predicted temporal blocks by deriving the first residual samples by means of a re-transformation applied to the transform coefficients signaled in the data stream for the respective transform coded temporal block.

34. Decoder of claim 33, configured to decode the transform coefficients for the respective transform coded temporal block from the data stream by decoding an end-sample position from the data stream and inferring that all transform coefficients of the respective transform coded temporal block following the end-sample-position along a transform coefficient coding order are zero.

35. Decoder of claim 1, wherein the set of prediction modes comprises one or more of
a DC prediction mode according to which the prediction signal of the respective temporal block is determined to by a constant function with a determination of a constant of the constant function based on predetermined already decoded samples preceding the respective temporal block,
one or more linear prediction modes according to which the prediction signal of the respective temporal block is determined to by a linear function with a determination of at least one of a slope and an offset of the linear function based on predetermined already decoded samples preceding the respective temporal block,
a block-copy prediction mode according to which the prediction signal of the respective temporal block is predicted based on one or more reference block portions of already decoded samples preceding the respective temporal block offset relative to the respective temporal block at a position signaled for the respective temporal block in the data stream,
a cross-channel prediction mode according to which the prediction signal of the respective temporal block is predicted based on one or more reference coded channels out of coded channels which represent a multi-channel signal coded into the data stream and to be decoded from the data stream by the decoder, and one of which is represented by the digital time-varying signal, and
a bypass prediction mode according to which the prediction signal of the respective temporal block is set to zero.

36. Decoder of claim 35, wherein a set of non-bypass prediction modes comprises one or more of the DC prediction mode, the one or more linear prediction modes, the block-copy prediction mode and the cross-channel prediction mode.

37. Decoder of claim 1, wherein the digital time-varying signal is a predetermined coded channel of coded channels representing a multi-channel digital signal.

38. Decoder of claim 37,
wherein the multi-channel digital signal is acquired by at least one of Electrocardiography, Electroencephalography, Electromyography or seismic measurement, and/or
wherein the multi-channel digital signal is a bio-physiological waveform data such as an electroencephalography signal, an electrocardiogram, or an electromyography signal, or seismic waveform data.

39. Encoder for encoding a digital time-varying signal into a data stream, configured to
encode the digital time-varying signal into the data stream in temporal blocks by encoding each temporally residual-predicted temporal block of the digital time-varying signal by
predicting the respective temporally residual-predicted temporal block using a selected prediction mode out of a set of prediction modes to acquire a prediction signal, and
determining a prediction residual signal of the respective temporally residual-predicted temporal block,
wherein, in the determining the prediction residual signal, sequentially encode second-stage-predicted residual samples of residual samples of the respective temporally residual-predicted temporal block along a sample order by
deriving a second-stage residual sample prediction value for a currently encoded second-stage-predicted residual sample based on already encoded residual samples within a template of a predetermined number of sample positions preceding the currently encoded second-stage-predicted residual sample in sample order,
encoding a second-stage-correction value for the currently encoded second-stage-predicted residual sample into the data stream.

40. Method for decoding a digital time-varying signal from a data stream, the method comprising
decoding the digital time-varying signal from the data stream in temporal blocks by decoding each temporally residual-predicted temporal block of the digital time-varying signal by
predicting the respective temporally residual-predicted temporal block using a selected prediction mode out of a set of prediction modes to acquire a prediction signal, determining a prediction residual signal of the respective temporally residual-predicted temporal block, and
correcting the prediction signal using the prediction residual signal,
wherein, in the determining the prediction residual signal, sequentially decode second-stage-predicted residual samples of residual samples of the respective temporally residual-predicted temporal block along a sample order by
deriving a second-stage residual sample prediction value for a currently decoded second-stage-predicted residual sample based on already decoded residual samples within a template of a predetermined number of sample positions preceding the currently decoded second-stage-predicted residual sample in sample order,
decoding a second-stage-correction value for the currently decoded second-stage-predicted residual sample from the data stream, and
correcting the second-stage residual sample prediction value using the second-stage-correction value.

41. Method for encoding a digital time-varying signal into a data stream, the method comprising
encoding the digital time-varying signal into the data stream in temporal blocks by encoding each temporally residual-predicted temporal block of the digital time-varying signal by
predicting the respective temporally residual-predicted temporal block using a selected prediction mode out of a set of prediction modes to acquire a prediction signal, and
determining a prediction residual signal of the respective temporally residual-predicted temporal block,
wherein, in the determining the prediction residual signal, sequentially encode second-stage-predicted residual samples of residual samples of the respective temporally residual-predicted temporal block along a sample order by
deriving a second-stage residual sample prediction value for a currently encoded second-stage-predicted residual sample based on already encoded residual samples within a template of a predetermined number of sample positions preceding the currently encoded second-stage-predicted residual sample in sample order,
encoding a second-stage-correction value for the currently encoded second-stage-predicted residual sample into the data stream.

42. Data stream encoded using the method according to claim 41.

43. Non-transitory digital storage medium having a computer program stored thereon to perform the method of claim 40 when said computer program is run by a computer.

44. Non-transitory digital storage medium having a computer program stored thereon to perform the method of claim 41 when said computer program is run by a computer.
